(19) United States
(12) Patent Application Publication
(10) Pub. No.: US 2026/0203459 A1
(43) Pub. Date: Jul. 16, 2026

(54) COLOR PREDICTION AND COLOR MATCHING METHODS AND APPARATUSES WITH IMPROVED ACCURACY

(71) Applicant: BASF COATINGS GMBH, Muenster (DE)

(72) Inventors: Guido BISCHOFF, Muenster (DE); Lena ZINK, Muenster (DE)

(21) Appl. No.: 19/127,977

(22) PCT Filed: Nov. 20, 2023
(86) PCT No.: PCT/EP2023/082407

§ 371 Date: May 7, 2025

(30) Foreign Application Priority Data
Nov. 23, 2022 (EP) 22209105.0

(51) Int. Cl. G06F 30/17

(52) U.S. Cl. CPC G06F 30/17

(57) ABSTRACT

Disclosed herein are a method and apparatus for determining a correction term for a color prediction model to allow reliable color prediction and color matching operations using input data being determined under different physical conditions than the color data associated with a reference coating used as a standard. Further disclosed herein are color prediction and color matching methods and apparatuses showing improved accuracy due to the use of the correction term determined according to the method.

### TECHNICAL FIELD

The invention relates to a computer-implemented method for providing a correction term for a color prediction model, a computer-implemented method and apparatus for determining the color of an adjusted sample coating being present under second physical conditions based on color data of the adjusted sample coating being present under first physical conditions, a computer-implemented method and apparatus for determining a second adjusted sample coating formulation to match the color of a reference coating being present under a second physical conditions based on color data of a first adjusted sample coating being present under a first physical condition, a use of the correction term determined by the inventive method, and a computer program element.

### TECHNICAL BACKGROUND

The present disclosure relates, in general terms, to color prediction and color matching methods and apparatuses, such computer-aided color prediction and color matching methods.

Color adjustment of a sample coating formulation to match the color of a reference coating is an iterative process. Starting with a preliminary sample coating formulation, said preliminary sample coating formulation normally has to be adjusted several times until an adjusted sample coating having a color which is sufficiently matching the color of the reference coating is found, rendering the color adjustment process time consuming and expensive.

To decrease the time and costs associated with color adjustments, computer-aided color prediction and color matching methods based on physical models describing the interaction of light with scattering or absorbing media, e. g. with colorants or pigments present in coatings, are used nowadays. Said physical models are able to predict the light reflectance properties (e.g. the color data) of a coating based on an information about the formulation of the coating material used to prepare the respective coating together with optical constants describing the absorption and scattering properties of formulation components, such as colorants or pigments, in the context of the respective physical model. Said specific optical properties of colorants may be determined based on coatings being present under defined physical conditions, such as in a dry physical condition (e.g. being dried and/or cured) or a wet physical condition (e.g. not being dried and cured) from known coating formulation data and measured coating reflectance data. Thus, color prediction and color matching methods using said physical models and optical constants are always associated with the physical condition of the coatings used to determine the optical constants.

However, color tolerances for a reference coating are defined for a specific physical condition of the reference coating, such as a dry state (e.g. being dried and/or cured), while the produced sample coating material may be present in different physical condition, such as a wet condition (e.g. not being dried and cured). Use of data of the sample coating being present under different physical conditions than the reference coating for color prediction and color matching methods using said physical models and optical constants typically results in a high inaccuracy since the optical properties, such as reflectance properties, of a coating highly depend on the physical conditions of the coating, e.g. whether the coating is present in a wet condition or a dry condition or the application process used to apply the coating material onto a substrate.

Due to this high inaccuracy, the color of each adjusted coating associated with each adjusted sample coating formulation obtained within the color matching process still has to be measured under physical conditions being identical to the physical condition of the reference coating. Thus, for example, if color data of a reference coating present in a dry state is to be used for comparison, each adjusted sample coating formulation has to be applied using the same application process than for the reference coating to a substrate and dried and/or cured to obtain the same physical condition prior to determining the color data of said adjusted sample coating.

Hence, there is a need to provide color prediction and color matching methods which result in more accurate results, thus avoiding preparation of cured adjusted sample coatings after each adjustment of the sample coating formulation during color matching operations.

An object of the present disclosure is therefore to provide color prediction and color matching methods and apparatuses which result in more accurate color prediction and color matching results, for example if data of a sample coating or adjusted sample coating being present under different physical conditions than the reference coating is used within the color prediction and/or color matching methods.

### SUMMARY

In an aspect the disclosure relates to a computer-implemented method for providing a correction term for a color prediction model, said correction term being associated with an adjusted sample coating being present under at least two different physical conditions, said method comprising:
receiving by at least one processor via a communication interface a request to provide
   a color difference (CD1) between the measured color data of the adjusted sample coating being present under a first physical condition and the predicted color data of the adjusted sample coating being present under the first physical condition,
   a color difference (CD2) between the measured color data of a sample coating being present under the second physical condition and the measured color data of the sample coating being present under the first physical condition, said sample coating being associated with the adjusted sample coating, and
   a color difference (CD3) between the predicted color data of the adjusted sample coating being present under the second physical condition and the predicted color data of the adjusted sample coating being present under the first physical condition; and
in response to the request, determining with the at least one processor the correction term for the color prediction model using the provided color differences (CD1) to (CD3); and
providing the determined correction term for the color prediction model via the communication interface.

In a further aspect, the disclosure relates to a computer-implemented method for determining the color of an adjusted sample coating being present under second physical conditions based on color data of the adjusted sample coating being present under first physical conditions, said method comprising:
receiving by at least one processor via a communication interface a request to provide
   a color difference between the measured color data of a sample coating being present under the second physical condition and the predicted color data of the sample coating being present under the second physical condition, said sample coating being associated with the adjusted sample coating,
   optical data of individual color components associated with the first physical condition,
   adjusted sample coating data including the formulation of the adjusted sample coating,
   condition adaption parameters associated with the difference between the first and the second physical condition of the adjusted sample coating,
   the correction term for the color prediction model determined according to the computer-implemented method for providing a correction term for a color prediction model disclosed herein,
   a color prediction model configured to predict the color of the adjusted sample coating being present under the second physical condition by using as input data the color difference, the optical data of individual color components, the condition adaption parameters, the adjusted sample coating data, and the correction term; and
in response to the received request, determining with the at least one processor color data of the adjusted sample coating being present under the second physical condition using the color prediction model and the data provided in step (a); and
providing the determined color data of the adjusted sample coating being present under the second physical condition via the communication interface.

In yet a further aspect, the disclosure relates to a computer-implemented method for determining a second adjusted sample coating formulation to match the color of a reference coating being present under a second physical conditions based on color data of a first adjusted sample coating being present under a first physical condition, said method comprising:
receiving by at least one processor via a communication interface a request to provide
   a color difference between the measured color data of a sample coating being present under the second physical condition and the predicted color data of the sample coating being present under the second physical condition, said sample coating being associated with the first adjusted sample coating,
   optical data of individual color components associated with the first physical condition,
   reference coating data including color data of the reference coating being present under the second physical conditions,
   first adjusted sample coating data including the formulation of the first adjusted sample coating,
   condition adaption parameters associated with the difference between the first and the second physical condition of the first adjusted sample coating,
   the correction term for the color prediction model determined according to the computer-implemented method for providing a correction term for a color prediction model disclosed herein,
   a color prediction model configured to predict the color of the second adjusted sample coating being present under the second physical condition by using as input data the color difference, the optical data of individual color components, the reference coating data, the first adjusted sample coating data, the condition adaption parameters, and the correction term; and
in response to the request, determining with the at least one processor a second adjusted sample coating formulation using the color prediction model and data provided in step (a); and
providing the determined second adjusted sample coating formulation via the communication interface.

In yet a further aspect, the disclosure relates to an apparatus comprising: one or more computing nodes; and one or more computer-readable media having thereon computer-executable instructions which, when executed by the one or more computing nodes, cause the apparatus to perform the computer-implemented methods disclosed herein.

In yet a further aspect, the disclosure relates to the use of a correction term as determined according to the computer-implemented methods disclosed herein to improve the accuracy of color data of an adjusted sample coating being present under a second physical condition, the color data being predicted by a color prediction model based on color data of the adjusted sample coating being present under first physical conditions.

In yet another aspect the present disclosure relates to a computer program element, such as a computer readable storage medium, a computer program or a computer program product, comprising instructions, which when executed by one or more computing node(s) or a computing system, direct the computing node(s) or the computing system to carry out the steps of the computer-implemented methods disclosed herein.

In yet another aspect the present disclosure relates to a computer program element, such as a computer readable storage medium, a computer program or a computer program product, comprising instructions, which when executed by the apparatuses disclosed herein, direct the apparatuses to carry out steps the apparatuses disclosed herein are configured to execute.

Any disclosure and embodiments described herein relate to the methods, the apparatuses and the computer program element lined out above and below and vice versa. Advantageously, the benefits provided by any of the embodiments and examples equally apply to all other embodiments and examples and vice versa.

The methods, apparatuses and computer program elements of the present disclosure allow to more accurately predict the optical properties, such as the color, of an adjusted sample coating formulation, e.g. a sample coating formulation already having been adapted at least once (for example by tinting a produced batch of a sample coating formulation at least once), being present under a first physical condition, such as a dry state (e.g. being dried and/or cured), based on optical property data, such as color data, of the adjusted sample coating being present under a second physical condition, such as a wet state (e.g. not being dried and cured). Thus, for example, the predicted color of the adjusted sample coating being present in a dry state more accurately matches the color of a reference coating being present in a dry state even though the prediction is based on data of the adjusted sample coating being present in a wet state and vice versa.

The same applies to color matching methods of the present disclosure, which allow to more accurately calculate an adjusted formulation of a sample coating to match the optical properties of a reference coating being present under a first physical condition (such as a dry state) based on data associated with a sample coating or a previous adjustment of the sample coating being present under a second physical condition (such as a wet state) or vice versa.

The improved accuracy of the color prediction and color matching methods of the present disclosure is obtained by determining a correction term for the physical model used within color prediction and/or color matching operations. Said correction term transforms the systematical error of the physical model for the second condition (such as a wet state) to the systematical error of the physical model for the first physical condition (such as a dry state) or vice versa. Transforming the systematical error from the physical condition of the sample coating or adjusted sample coating to the respective physical condition of the reference coating allows to consider the strong influence of the physical condition of the respective coating on its optical properties, such as reflectance properties, thus leading to significantly improved prediction and matching results.

The significantly improved prediction and matching results allow to reduce the amount of coated substrates (also called spray-outs hereinafter) which have to be prepared during color matching operations to ensure that the adjusted sample coating formulation results in the optical properties which are within the given tolerances associated with the reference coating. The reduced amount of necessary spray-outs saves costs and allows to increase the efficiency of the coating material production process. Moreover, the reduced amount of spray-outs results in improved reproducibility of the optical properties of the adjusted sample coatings because the influence of the preparation of spray-outs on the optical properties of the resulting coating is avoided.

Moreover, the color prediction and color matching methods according to the present disclosure allow to automatize the tinting process in coating material production, where the produced batch normally needs to be tinted to ensure a sufficient color match with the respective reference coating. Since the produced coating material is normally in a wet state, the tinting processes are also performed in a wet state. Accurate prediction of necessary tinting of a produced coating material batch using the color prediction and color matching methods according to the present disclosure allows to significantly increase production efficiency by reducing or avoiding preparation of spray-outs to ensure a sufficient degree of color matching between the produced coating material batch and the reference coating, thus reducing costs and time associated with the production of pigmented coating materials.

### EMBODIMENTS

In the following, terminology as used herein and/or the technical field of the present disclosure will be outlined by ways of embodiments and/or examples. Where examples are given, it is to be understood that the present disclosure is not limited to said examples. All terms and definitions used herein are understood broadly and have their general meaning.

In an embodiment, correction term may refer to a term introduced into a physical model, such as the color prediction model, said term being necessary to bring the results obtained with said physical model into line with measurement results.

In an embodiment, color prediction model may refer to a deterministic model based on physical laws which is configured to predict color data of a coating. The color prediction model may, for example, be based on physical laws describing the light absorption and light scattering properties of pigmented systems, such as pigmented coatings.

In an embodiment, coating may refer to the entirety of layers of coating materials that are to be applied or have been applied to a substrate. The coating may be characterized in more detail according to various criteria, such as the type of coating material (painting, lacquering, powder coating) or the type of the application process (painting, spray coating, dip coating, casting coating, filler coating, etc.). The one or more coating layers may be prepared by applying respective coating materials to the substrate, for example by using one of the aforementioned application processes. After application, the coating material may form a continuous layer (e.g. coating film) on the substrate and said continuous film may be dried and/or cured. If more than one coating material is applied to the substrate, each applied coating material may be dried and cured separately or curing may be performed jointly, e.g. after at least two coating material have been applied and optionally dried.

In an embodiment, reference coating may refer to a coating having defined properties, such as defined colorimetric properties. The reference coating may be prepared by applying at least one defined coating material, e.g. reference coating material, to a surface using a defined application process and drying and/or curing said applied coating material. At least one of the defined coating materials may contain at least one colorant.

In one embodiment, sample coating may refer to a coating that is evaluated in comparison with the reference coating with respect to at least one defined property, such as colorimetric properties. The sample coating may be prepared as described for the reference coating, e.g. by using a respective sample coating material.

In one embodiment, adjusted sample coating may refer to a sample coating where at least one component present within the sample coating formulation has been modified at least once, for example by modifying the amount and/or type of said component, with respect to the sample coating formulation (e.g. the unmodified sample coating formulation). The sample coating used as a basis for preparation of the adjusted sample coating may be termed “sample coating associated with the adjusted sample coating”. To denote the number of adjustments with respect to the sample coating, a sequential number may be used in combination with the term “adjusted sample coating”. For example, the first adjusted sample coating may refer to the first adjustment of the sample coating formulation while the term second adjusted sample coating may refer to the second adjustment of the sample coating formulation, etc., The terms “formulation”, “color formulation” and “paint formulation” are used synonymously herein.

In one embodiment, physical condition may refer to the state of the respective coating, such as reference coating, sample coating, adjusted sample coating of first adjusted sample coating and second adjusted sample coating. The state may be a wet state or a dry state. The wet state may represent a state of the respective coating not having been dried and/or cured, for example by using elevated temperatures. Thus, the wet state may represent a produced coating material, for example being present within a measurement cell, and the dry state may represent a dried and/or cured state of the coating produced from the respective coating material. Dried state may refer to a state of the coating after vaporization of organic solvents and/or water present in a coating material or film after application of the coating material to the substrate. Drying may be performed, for example at 15 to 35° C. and/or at elevated temperatures of, for example 40 to 90° C. While the coating material is free-flowing at least directly after the application and may form a homogeneous, smooth coating film by leveling, drying of said formed coating film results in said film no longer being free-flowing. However, the formed coating is still soft and/or tacky and does undergo further significant changes in its properties, such as hardness or adhesion on the substrate, under further exposure to curing conditions as described in the following. Cured state may refer to a state of the coating which does not undergo any further significant changes in its properties, such as hardness or adhesion on the substrate, upon further exposure to curing conditions, such as elevated temperatures (for example 80 to 200° C.) for a period of 10 to 60 minutes. The cured coating is—in contrast to a dried coating-no longer soft or tacky, but has been conditioned as a solid coating. The state may also be a state associated with a specific application process, such as a spray coating, a roll coating, a brush coating, a spin coating, etc.,

In one embodiment, application process may refer to the application of a coating material to a substrate. The application of a coating material to a substrate may further include post-treatment of the applied coating material, for example by drying and/or curing at elevated temperatures and/or for a prolonged duration of time. Application of a coating material to a substrate can be performed by various methods known in the state of the art, such as spray application, dip application, roll application, spin application, electrocoating, etc.,

In one embodiment, individual color component may refer to separate components present within a coating material formulation, such as the sample coating formulation, the reference coating formulation or the adjusted sample coating formulation. Examples of individual color components include pigments, such as color and effect pigments, binders, solvents and additives, such as for example matting pastes.

In one embodiment, optical data of individual color components may refer to optical properties and/or the specific optical constants of individual color components. The optical constants of the individual color components are parameters in a physical model which may be determined by preparing coatings using defined batches of pigment pastes and determining the optical properties, for example by measuring the reflectance spectra of the prepared coatings with a spectrophotometer. From the reflectance spectra and the corresponding formulation data, the specific optical properties, such as the K/S constants, may be determined and assigned as optical data to the respective individual color components. The terms “optical data of individual color components”, “optical data of the individual color components” or “optical data of the colorants” are used synonymous.

In one embodiment, systematical error of the color prediction model may refer the limitations of the physical model and/or a systematical error within the optical data of the individual color components contained in the respective coating formulation. The systematical error within the optical data of individual color components may arise from differences in colorant strength characteristics of pigment pastes because said characteristics deviate from batch to batch due to deviations in the raw materials (such as pigments) used to prepare the pigment pastes. In one example, the systematical error of the color prediction model may represent the difference between the color data of a coating predicted by the color prediction model and the measured color data of said coating. In another example, the systematical error may represent the difference between the color data of a coating/coating material predicted by the color prediction model for a first physical condition and color data of a coating/coating material predicted by the color prediction model for a second physical condition. The systematical error of the color prediction model may be adjusted by considering the systematical error associated with a color prediction for the sample coating or a previous adjustment of the sample coating (e.g. the previous systematical error). The previous systematical error may be considered, for example, by adding said systematical error to the predicted color of the respective adjusted sample coating. For example, if the systematical error associated with a color prediction of an adjusted sample coating is to be adjusted, the systematical error associated with the sample coating used to prepare the adjusted sample coating (e.g. the difference between the measured and predicted sample coating color data) is considered, for example by adding said systematical error to the predicted color data of the adjusted sample coating.

In one embodiment, condition adaption parameters may refer to differences, such as specific transfer functions, between the first physical condition in comparison to the second physical condition (e. g. differences between a wet state and a dry state of the respective coating or differences between a first application process and a second application process). Condition adaption parameters may include differences associated with pigments, differences associated with different physical conditions and/or differences associated with appearance changes upon changing the physical condition. Differences associated with pigments may include effect flake orientation adaption, the effectivity of color pigments and/or the effectivity of effect pigments. Effect flake orientation adaption may allow to consider the better or worse flake orientation in effect coatings (e.g. coatings comprising at least one coating layer containing effect pigments) and can be used to adjust their lightness-/color-flop behavior. The effectivity of color pigments may allow to consider color pigments being more or less effective to adjust the tinting strength differences of solid colorants which could be caused, for example, by shearing effects or by agglomerates. The effectivity of effect colorants may allow to consider effect pigments being more or less effective to adjust differences of the reflection power of effect colorants which could be caused, for example, by over-spray losses or settling or leaving effects. Differences associated with different physical conditions may include light loss adaption for a coating material being present under wet conditions in a cuvette or measuring cell, and/or a conversion term for the refractive index between different physical conditions, such as wet and dry conditions. Differences associated with appearance changes upon changing the physical condition may include compensation of components having a certain degree of opacity, such as mixing clears in coatings material being present under wet conditions, and which turn transparent upon changing the physical condition, such as upon drying and/or curing the coatings. The condition adaption parameters may relate to a systematical error of the color prediction model associated with the prediction of a color of a coating formulation under a first physical condition in comparison to the prediction of the color of the coating formulation under second physical conditions. This systematical error may be considered, for example, by adding said systematical error to the predicted color of the respective coating formulation. For example, if the condition adaption parameters associated with a color prediction of an adjusted sample coating are to be considered, this systematical error may be adding added to the predicted color data of the adjusted sample coating.

In an embodiment, a computing node may refer to any device or system that includes at least one physical and tangible processor, and a physical and tangible memory capable of having thereon computer-executable instructions that are executed by said processor. Computing node(s) may, for example, be handheld devices, production facilities, sensors, monitoring systems, control systems, appliances, laptop computers, desktop computers, mainframes, data centers, or even devices that have not conventionally been considered a computing node, such as wearables (e.g., glasses, watches or the like). The memory may take any form and depends on the nature and form of the computing node.

In an embodiment processor may refer to any circuitry, such as arbitrary logic or a quantum circuit, configured to perform basic operations of a computer or system, and/or, generally, to a device which is configured for performing calculations or logic operations. In particular, the processor or computer processor may be configured for processing basic instructions that drive the computer or system. It may be a semi-conductor based processor, a quantum processor, or any other type of processor configured for processing instructions. As an example, the processor may be or may comprise a Central Processing Unit (“CPU”). The processor may be a (“GPU”) graphics processing unit, (“TPU”) tensor processing unit, (“CISC”) Complex Instruction Set Computing microprocessor, Reduced Instruction Set Computing (“RISC”) microprocessor, Very Long Instruction Word (“VLIW”) microprocessor, or a processor implementing other instruction sets or processors implementing a combination of instruction sets. The processing means may also be one or more special-purpose processing devices such as an Application-Specific Integrated Circuit (“ASIC”), a Field Programmable Gate Array (“FPGA”), a Complex Programmable Logic Device (“CPLD”), a Digital Signal Processor (“DSP”), a network processor, or the like. The methods, systems and devices described herein may be implemented as software in a DSP, in a micro-controller, or in any other side-processor or as hardware circuit within an ASIC, CPLD, or FPGA. It is to be understood that the term processor may also refer to one or more processing devices, such as a distributed system of processing devices located across multiple computer systems (e.g., cloud computing), and is not limited to a single device unless otherwise specified.

In an embodiment memory or data storage medium may refer to a physical system memory, which may be volatile, non-volatile, or a combination thereof. The memory may include non-volatile mass storage such as physical storage media. The memory may be a computer-readable storage media such as RAM, ROM, EEPROM, CD-ROM, or other optical disk storage, magnetic disk storage, or other magnetic storage devices, non-magnetic disk storage such as solid-state disk or any other physical and tangible storage medium which can be used to store desired program code means in the form of computer-executable instructions or data structures and which can be accessed by the computing system. Moreover, the memory may be a computer-readable media that carries computer-executable instructions (also called transmission media). Further, upon reaching various computing system components, program code means in the form of computer-executable instructions or data structures can be transferred automatically from transmission media to storage media (or vice versa). For example, computer-executable instructions or data structures received over a network or data link can be buffered in RAM within a network interface module (e.g., a “NIC”), and then eventually transferred to computing system RAM and/or to less volatile storage media at a computing system. Thus, it should be understood that storage media can be included in computing components that also (or even primarily) utilize transmission media.

In an embodiment, computer readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Java, Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention. In an embodiment, computer readable program instructions may be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device may receive the computer readable program instructions from the network and may forward the computer readable program instructions for storage in a computer readable storage medium within the respective computing/processing device.

In an embodiment, communication interface may refer to a software and/or hardware interface for establishing communication such as transfer or exchange or signals or data. Software interfaces may be e. g. function calls, APIs. Communication interfaces may comprise transceivers and/or receivers. The communication may either be wired, or it may be wireless. Communication interface may be based on or it supports one or more communication protocols. The communication protocol may a wireless protocol, for example: short distance communication protocol such as Bluetooth®, or WiFi, or long distance communication protocol such as cellular or mobile network, for example, second-generation cellular network (“2G”), 3G, 4G, Long-Term Evolution (“LTE”), or 5G. Alternatively, or in addition, the communication interface may even be based on a proprietary short distance or long distance protocol. The communication interface may support any one or more standards and/or proprietary protocols.

In one embodiment, database may refer to a collection of related information that can be searched and retrieved. The database may be a searchable electronic document, such as a numerical, alphanumerical, or textual document, a searchable PDF document or a Microsoft Excel® spreadsheet; or a database commonly known in the state of the art. The database may be a set of electronic documents, photographs, images, diagrams, data, or drawings, residing in a computer readable storage media that can be searched and retrieved. A database can be a single database or a set of related databases or a group of unrelated databases. Related databases may include databases that comprise at least one common information element in the related databases that can be used to relate such databases.

A paint production process for a given color typically starts with an initial coating material formulation or sample coating material formulation, e. g. a formulation loaded from a database. An initial batch of coating material is then fabricated according to this initial coating material formulation by adding at least one pigment paste (also called colorant hereinafter) to a base varnish containing binders, solvents and optionally additives. The pigment paste is an intermediate product containing a color imparting component (such as a pigment) in a matrix (typically a binder, solvents and optionally additives). The initial coating material formulation normally comprises reduced amounts of color imparting components compared to the final coating material formulation to avoid that the produced batch of coating material becomes too dark because of the use of too high amounts of color imparting component(s). After production, the corresponding color data of the produced coating material batch is measured under physical conditions being identical to the ones of the reference coating and compared with color data of a reference coating being present under defined physical conditions, such as in a dry state or having been produced by a defined application method, such as spray application. Instead of measuring the color data of the produced batch, the color data of a previously produced batch of the same coating material may be used for comparison with the reference coating as long as the color deviation between different batches is assumed to be low. Due to the reduced amounts of color imparting components, the produced coating material batch normally has a significant residual color difference compared to the reference coating. Thus, the initial coating material formulation must be modified in a subsequent color adjustment process such that the residual color difference between the color data of the adjusted sample coating and the reference coating is below a defined threshold value.

An adjusted sample coating formulation can be calculated from the sample coating formulation as well as the color data of the sample coating and the reference coating using a color prediction model. However, the color data of an adjusted sample coating being present in a wet state significantly differs from the color of said adjusted sample coating being present in a dry state. The same applies to the use of different application processes to apply the adjusted sample coating material to a substrate, for example use of spray application vs. use of roll application.

Use of color data of an adjusted sample coating present in different physical condition than the reference coating, for example use of color data acquired in a wet state right after adjusting the produced sample coating batch, within color prediction or color adjustment processes normally results in a significant deviation between the color data predicted for adjusted sample coating for the physical condition associated with the reference coating and the color data measured for the adjusted sample coating for the physical condition associated with the reference coating due to the significant influence of the physical condition on the color data. Therefore, an adjusted sample coating matching the physical condition associated with the reference coating must normally be prepared from an adjusted sample coating material and the color data of said prepared adjusted sample coating must be determined and compared with the color data of the reference coating to ensure a sufficient degree of color matching. This procedure, however, is time consuming, associated with high costs and increases production times of tinted coating material batches.

It is therefore highly desirable to provide methods and apparatuses which result in more accurate color prediction and color matching results if data of a sample coating or adjusted sample coating being present under different physical conditions than the reference coating is used for the color prediction and/or color matching. Such methods and apparatuses would reduce or avoid preparation of adjusted sample coatings matching the physical conditions associated with the reference coating to ensure a sufficient color match.

These and other objects, which become apparent upon reading the following description, are solved by the subject matters of the independent claims. The dependent claims refer to embodiments of the present disclosure.

In an embodiment, the color prediction model is configured to predict the color data of a coating based on input data, said input data including coating formulation data and optical data of individual color components. Coating formulation data may include the data on the components and amounts of said components present within the coating material used to prepare the coating. Data on the components may be used to determine the respective optical data of individual color components to be used for the prediction of the color data. Such color prediction models are well known in the state of the art, for example as described in Georg A. Klein; Farbenphysik für industrielle Anwendungen; Chapter 7-Farbrezept-Berechnung, June 2004.

Optical data of individual color components may include optical constants of the individual color components, such as wavelength dependent scattering and absorption properties of the individual color components. The optical constants may further include the orientation of individual color components, such as effect pigments, within the coating.

In an embodiment, the correction term includes the systematical error of the color prediction model upon predicting color data of the adjusted sample coating being present under the second physical condition based on input data associated with the adjusted sample coating being present under the first physical condition. The systematical error may be due to the fact that the physical conditions of the coating significantly influence the color and thus the color data as previously described. The correction term may be considered, for example, by adding said correction term to the color of the respective coating formulation predicted by the color prediction model based on the input data.

When predicting color data for a first physical condition using input data associated with second physical conditions or vice versa, the dependency of the color data on the physical conditions may result in a strong deviation of the predicted color data from the observed color data. The correction term may serve to correct the difference in color data arising from the use of different physical conditions at least partially, such that the color data predicted by the color prediction model for a physical condition when using said correction term is more accurate than without the of said correction term. The correction term may thus allow to improve the accuracy of the color data predicted by the color prediction model even if the input data is associated with a different physical condition than the “target coating” or reference coating. For instance, the use of the correction term may allow to predict the color data of an adjusted sample coating being present under dry conditions more accurately when using as input data associated with the adjusted sample coating being present under wet conditions. This may result in less coatings having to be prepared from the adjusted sample coating material to allow a sufficiently correct calculation of a further adjustment, such as a further adjustment of the formulation, of the adjusted sample coating, such that the color of the coating resulting from the further adjusted sample coating material sufficiently matches the color of the reference coating used for comparison.

In an embodiment, the first physical condition includes a wet state, or a physical condition associated with a first application process. The first application process may be an application process commonly used to apply a coating material to at least part of the surface of a substrate. Suitable application processes include, for example, dipping, bar coating, spraying or rolling. Spraying may include spray application methods, for example compressed air spraying (pneumatic application), airless spraying, high-speed rotation, electrostatic spray application (ESTA), optionally in association with hot-spray application, for example hot-air spraying.

In an embodiment, the second physical condition includes a dry state, or a physical condition associated with a second application process. The second application process is different from the first application process. For instance, the first application process may be a bar coating or a dip coating process and the second application process may be a spray coating process or vice versa.

In an embodiment, the color data includes reflectance data, color space data, such as CIEL*a*b* values or CIEL*C*h* values, gloss data, texture parameters, such as texture characteristics and/or coarseness characteristics, or a combination thereof. The color data, such as reflectance data, may be determined using a multi-angle spectrometer. The color space data, e.g., CIEL*a*b* values, may be calculated from the acquired reflectance data and the radiation function of the light source (see for example, ASTM E2194-14 (2017) and ASTM E2539-14 (2017). Texture parameters may be determined from texture images acquired under defined light conditions and at defined angles. The texture parameters may be calculated from the obtained images. Examples of such calculated texture parameters include the textural values G diffuse or Gdiff (so called graininess or coarseness or coarseness value or coarseness characteristic) which describes the coarseness characteristics of a coating layer under diffuse illumination conditions, Si (sparkle intensity), and Sa (sparkle area) which describe the sparkle characteristics of a coating layer under directional illumination conditions, as introduced by the company Byk-Gardner (“Den Gesamtfarbeindruck objektiv messen”, Byk-Gardner GmbH, JOT 1.2009, vol. 49, issue 1, pp. 50-52). The texture parameters introduced by Byk-Gardner are determined from gray scale images. It is also possible for texture parameters to be determined from color images, as e. g. introduced by the company X-Rite with the MA-T6 or MA-T12 multiangle spectrophotometers.

In an embodiment, providing the predicted color data of the adjusted sample coating being present under the first physical condition includes
receiving model input data including adjusted sample coating formulation data and optical data of individual color components associated with the first physical condition,
receiving a color prediction model configured to predict color data of a coating using coating formulation data and optical data of individual color components,
predicting said color data using the received color prediction model and the received model input data.

The model input data may be received via the communication interface. The model input data may be stored on a data storage medium, such as a database, and may be retrieved by the at least one processor based on data associated with the adjusted sample coating, such as an ID of the adjusted sample coating. The adjusted sample coating formulation data may contain data on the components and amounts of components present within the adjusted sample coating material. The optical data may be retrieved from the data storage medium based on the components present in the adjusted sample coating formulation.

The color prediction model may use the formulation data as well as the optical data associated with components present within the adjusted sample coating material to predict color data associated with the adjusted sample coating material. The predicted color data may be associated with the first physical condition since the optical data used for the color prediction is also associated with the first physical condition. For instance, if the optical data is associated with a wet condition (i.e. said data has been determined from coatings being present under wet conditions), the color data predicted by the color prediction model is also associated with a wet condition, i.e. the color prediction model predicts the color data for an adjusted sample coating being present under wet conditions. The predicted color data may be reflectance data. The predicted color data may be color space data, such as CIEL*a*b* values or CIEL*C*H* values.

Providing the predicted color data of the adjusted sample coating being present under the first physical condition may further include considering the systematical error of the color prediction model associated with the first physical condition. The systematical error of the color prediction model may be considered as a constant during the color prediction performed by the color prediction model. Considering the systematical error of the color prediction model may allow to improve the accuracy of the predicted color data.

The systematical error of the color prediction model associated with the first physical condition may be obtained by determining the difference between
the measured color data of the sample coating being present under the first physical condition, and
the predicted color data of the sample coating being present under the first physical condition.

The measured color data of the sample coating being present under the first physical condition may be obtained by preparing a sample coating from a respective sample coating material and measuring the color data of the prepared sample coating, for example using a multi-angle spectrophotometer as described previously.

The color data of the sample coating being present under first physical conditions may be predicted using the color prediction model mentioned previously as well as the sample coating formulation and optical data associated with the first physical conditions as input data for the color prediction model. The predicted color data of the sample coating may then be compared to the measured color data of the sample coating being present under first physical conditions. For instance, the color data of the sample coating may be measured under wet conditions. Suitable measurement methods may include the use of a measurement cell for liquid sample coating materials, such as a glass cuvette or a glass pane.

The systematical error of the color prediction model associated with the first physical condition may be obtained by determining the difference between
the measured color data of the adjusted sample coating being present under the first physical condition, and
predicted color data of the adjusted sample coating being present under the first physical condition.

The measured color data of the adjusted sample coating may be determined as previously described. The color data of the adjusted sample coating may be predicted using the color prediction model, the adjusted sample coating formulation data as well as the optical data as described previously.

In an embodiment, providing the predicted color data of the adjusted sample coating being present under the second physical condition includes
receiving model input data including adjusted sample coating formulation data and optical data of individual color components associated with the second physical condition or including adjusted sample coating formulation data, optical data of individual color components associated with the first physical condition and condition adaption parameters associated with the difference between the first and the second physical condition of the sample coating,
receiving a color prediction model configured to predict color data of a coating using coating formulation data, optical data of individual color components and optionally condition adaption parameters,
predicting said color data using the received color prediction model and the received model input data.

The model input data may be received via the communication interface as described previously. For instance, the adjusted sample coating formulation data may be stored on a data storage medium and may be retrieved by the at least one processor based on data associated with the adjusted sample coating, such as an ID of the adjusted sample coating. The adjusted sample coating formulation data may contain data on the components and amounts of components present within the adjusted sample coating material. The optical data may be retrieved from the data storage medium based on the components present in the adjusted sample coating formulation.

The optical data may be associated with the second physical condition, such as the dry state. In this case, the color prediction model may use the formulation data as well as the optical data associated with components present within the adjusted sample coating material to predict color data associated with the adjusted sample coating material being present in the dry state. The predicted color data may be associated with the second condition since the optical data used for the color prediction is also associated with the second condition. The predicted color data may be reflectance data. The predicted color data may be color space data, such as CIEL*a*b* values or CIEL*C*H* values.

The optical data may be associated with the first physical condition, such as a wet state. In this case, condition adaption parameters may be used to adapt the color predictions performed by the color prediction model using said optical data associated with the wet state to a dry state. This may allow to use the same optical data irrespective of the physical condition the color prediction is performed for, thus reducing the amount of samples that need to be prepared to determine said optical data as well as the amount of data that needs to be acquired and processed to determine said optical data.

The condition adaption parameters may be pre-configured (i.e. pre-defined) and/or may be calculated based on sample coating input data using a method configured to optimize condition adaption parameters by minimizing a cost function starting from a given set of initial condition adaption parameters and a color prediction model configured to predict the color data of the sample coating being present under the first physical condition by using as input data the formulation of the sample coating, optical data of individual color components associated with the first physical condition, and condition adaption parameters resulting from said method. The color prediction model may be the color prediction model described previously. The condition adaption parameters determined for the sample coating may correspond to the condition adaption parameters associated with the adjusted sample coating. This allows to determine condition adaption parameters from data readily available for the sample coating, thus avoiding providing further input data and/or performing further calculations to obtain input data necessary to determine the condition adaption parameters for the adjusted sample coating.

The cost function may include a color distance between the measured color data of the sample coating being present under the second physical condition and the color data of said sample coating predicted with the color prediction model.

The condition adaption parameters may be calculated by comparing the recursively predicted color data of the sample coating for the second physical condition with the measured color data of the sample coating until the given cost function falls below a given threshold. This allows to determine the condition adaption parameters required to account for the use of optical data associated with the first physical condition when predicting the color data of the adjusted sample coating being present under a second physical condition. For instance, the condition adaption parameters may be used to account for the use of optical data associated with a wet condition (i.e. determined from coatings being in a wet state) when predicting color data of the adjusted sample coating present in a dry state.

Providing the predicted color data of the adjusted sample coating being present under the second physical condition may further include considering the systematical error of the color prediction model associated with the second physical condition. The systematical error may be considered as a constant during the prediction of the color data of the adjusted sample coating being present under the second physical condition using the color prediction model. The systematical error may be considered, for example, by adding said systematical error to the predicted color of the adjusted sample coating being present under the second physical condition.

The systematical error of the color prediction model associated with the second physical condition may be obtained by determining the difference between
the measured color data of the sample coating being present under the second physical condition, and
predicted color data of the sample coating being present under the second physical condition.

The measured color data of the sample coating being present under the second physical condition may be obtained by preparing a sample coating from a respective sample coating material and measuring the color data of the prepared sample coating, for example using a multi-angle spectrophotometer as described previously. For instance, a sample coating in a dry state may be prepared by applying a sample coating material on a substrate and drying and/or curing the applied sample coating material to obtain the sample coating in dry state.

The color data of the sample coating being present under the second physical conditions may be predicted using the color prediction model as described previously.

In an embodiment, the correction term for the color prediction model using the provided color difference (CD1) to (CD3) is determined according to formula (I):

$$correction term = C D 1 \times \frac{Δ C D sample {coating}_{first phys . cond . \to second phys . cond .}^{measured}}{Δ C D adj . sample {coating}_{first phys . cond . \to second phys . cond .}^{predicted}}$$

(I). In this formula (I), the numerator of the fraction thus corresponds to color difference CD2 and the denominator of said fraction thus corresponds to color difference CD3.

CD1 in formula (I) may be determined according to formula (Ia):

$$C D adj . sample {coating}_{first phys . cond .}^{measured} - C D adj . sample {coating}_{first phys . cond .}^{predicted} . \qquad ( Ia )$$

In an embodiment, the color difference may correspond to the difference between measured and/or predicted data. The color difference may correspond to color difference (CD1), color difference (CD2) and/or color difference (CD3). For instance, color differences (CD1) to (CD3) may be determined using the respective color data, such as the measured color data and the predicted color data (e.g. for color differences (CD1) and (CD2)) and/or the predicted color data for the first and second physical condition (e.g. for color difference (CD3)).

In an embodiment, the adjusted sample coating data further includes data being indicative of the adjusted sample coating, the layer structure of the adjusted sample coating, instructions to prepare the adjusted sample coating formulation(s), the price or a combination thereof. The adjusted sample coating data may be retrieved from a data storage medium. For instance, data being indicative of the adjusted sample coating may be provided to the at least one processor and the processor retrieves said data using the received data. Data being indicative of the adjusted sample coating may include a color number, a color code, a bar code, a unique database ID associated with the adjusted sample coating, or a combination thereof. Instructions to prepare the adjusted sample coating formulation(s) may include mixing instructions.

In an embodiment, providing the determined color data of the adjusted sample coating being present under the second physical condition includes providing said determined color data, optionally in combination with further data, via the communication interface for display. The determined color data may be provided to a display device comprising a screen. Examples of further data displayed with the determined color data may include data contained in the adjusted sample coating data, condition adaption parameters, the correction term or a combination thereof.

The display device may comprise an enclosure housing the at least one processor performing the methods disclosed herein and the screen. The enclosure may be made of plastic, metal, glass, or a combination thereof.

The display device and the at least one processor may be configured as separate components, i.e. the display device may comprise an enclosure housing the screen but not the at least one processor performing the steps of the methods disclosed herein. The at least one processor may thus be present separately from the display device, for example in a further computing device, connected to the display device via a communication interface to allow data exchange. Use of a further computer processor being present outside of the display device allows to use higher computing power than provided by the processor of the display device, thus reducing the computing time necessary to perform the methods disclosed herein and therefore the overall time until the calculated color data is displayed on the screen of the display device. This allows to display the calculated color data ad hoc without requiring a display device with high computing power. The further computer processor may be located on a server, such that methods disclosed herein may be performed in a cloud computing environment. In this case, the display device may function as client device which is connected to the server via a network and which used to provide the input data . . .

The display device may be a mobile or a stationary display device. Stationary display devices include computer monitors, television screens, projectors etc., Mobile display devices include laptops or handheld devices, such as smartphones and tablets.

The screen of the display device may be constructed according to any emissive or reflective display technology with a suitable resolution and color gamut. Suitable resolutions are, for example, resolutions of 72 dots per inch (dpi) or higher, such as 300 dpi, 600 dpi, 1200 dpi, 2400 dpi, or higher. This guarantees that the generated appearance data can displayed in a high quality. A suitably wide color gamut is that of standard Red Green Blue (sRGB) or greater. In various embodiments, the screen may be chosen with a color gamut similar to the gamut perceptible by human sight. In an aspect, the screen of the display device is constructed according to liquid crystal display (LCD) technology, in particular according to liquid crystal display (LCD) technology further comprising a touch screen panel. The LCD may be backlit by any suitable illumination source. The color gamut of an LCD screen, however, may be widened or otherwise improved by selecting a light emitting diode (LED) backlight or backlights. In another aspect, the screen of the display device is constructed according to emissive polymeric or organic light emitting diode (OLED) technology. In yet another aspect, the screen of the display device may be constructed according to a reflective display technology, such as electronic paper or ink. Known makers of electronic ink/paper displays include E INK and XEROX. Preferably, the screen of the display device also has a suitably wide field of view that allows it to generate an image that does not wash out or change severely as the user views the screen from different angles. Because LCD screens operate by polarizing light, some models exhibit a high degree of viewing angle dependence. Various LCD constructions, however, have comparatively wider fields of view and may be preferable for that reason. For example, LCD screens constructed according to thin film transistor (TFT) technology may have a suitably wide field of view. Also, screens constructed according to electronic paper/ink and OLED technologies may have fields of view wider than many LCD screens and may be selected for this reason.

The display device may comprise an interaction element to facilitate user interaction with the display device. The interaction element may be a physical interaction element, such as an input device or input/output device, in particular a mouse, a keyboard, a trackball, a touch screen or a combination thereof. The interaction element may be used to provide the input data or to imitate further actions, as describe later on.

The color data of an adjusted sample coating being present under second physical conditions based on color data of the adjusted sample coating being present under first physical conditions may be determined using a color prediction model. The color prediction model may receive as input data
a color difference between the measured color data of a sample coating being present under the second physical condition and the predicted color data of the sample coating being present under the second physical condition, said sample coating being associated with the adjusted sample coating,
optical data of individual color components associated with the first physical condition,
adjusted sample coating data including the formulation of the adjusted sample coating,
condition adaption parameters associated with the difference between the first and the second physical condition of the adjusted sample coating,
the correction term for the color prediction model as previously described.

The color prediction model may be configured to predict the color of the adjusted sample coating by
predicting color data of the adjusted sample coating based on the optical data of individual color components, the condition adaption parameters and the adjusted sample coating data and
adding the color difference and the correction term to the predicted color data.

The color difference and the correction term may relate to systematical errors of the color prediction model associated with the prediction of the color of the adjusted sample coating being present under second physical conditions based on color data of the adjusted sample coating being present under first physical conditions. Such systematical errors may be added to the color (e.g. color data) predicted by the physical model based on the formulation of the adjusted sample coating, the optical data of individual color components and the condition adaption parameters.

In an embodiment, the computer-implemented method for determining the color of an adjusted sample coating being present under second physical conditions based on color data of the adjusted sample coating being present under first physical conditions further includes
providing color data of a reference coating being present under the second physical conditions,
calculating the color difference between the determined color data of the adjusted sample coating being present under the second physical condition and the provided color data of the reference coating being present under the second physical condition and
optionally providing the calculated color difference via the communication interface.

The color data of the reference coating may be provided by retrieving said color data from a data storage medium. For instance, data being indicative of the reference coating may be provided and the reference coating color data may be retrieved based on the provided data. Data being indicative of the reference coating may include a color number, a color code, a bar code, a unique database ID associated with the reference coating, or a combination thereof.

The color difference may be calculated using a color tolerance equation. The color tolerance equation may be selected from the Delta E (CIE 1994) color tolerance equation, the Delta E (CIE 2000) color tolerance equation, the Delta E (DIN 99) color tolerance equation, the Delta E (CIE 1976) color tolerance equation, the Delta E (CMC) color tolerance equation, the Delta E (Audi95) color tolerance equation, the Delta E (Audi2000) color tolerance equation or other color tolerance equations.

The calculated color difference may be provided via the communication interface for display as described previously.

In an embodiment, the computer-implemented method for determining the color of an adjusted sample coating being present under second physical conditions based on color data of the adjusted sample coating being present under first physical conditions further includes initiating at least one action associated with the calculated color difference. This may include comparing the calculated color difference to a predefined threshold value and initiation an action based on said calculation. For instance, an action may be initiated if the calculated color difference is above or below the predefined threshold value. The initiated action may depend on the result of the comparison. For instance, one or more actions may be associated with the calculated color difference being below the predefined threshold value while different action(s) may be associated with the calculated color difference being above the predefined threshold value. An action being associated with the calculated color difference being above the predefined threshold value may be initiating modification of the formulation of the adjusted sample coating to minimize the color difference with respect to the reference coating, such as described in relation to the method for determining a second adjusted sample coating formulation later on. The at least one action may be initiated by a user or may be initiated by the at least one processor.

Initiating at least one action may include providing the adjusted sample coating formulation to a printing device and/or a data storage medium and/or a filling line, optionally after determining whether the calculated color difference is below a predefined threshold value. For instance, the determined color difference being below a predefined threshold value may indicate that the color difference between the reference coating and the sample coating is sufficiently low, i.e. the quality of the sample coating in terms of color/appearance is sufficiently high for the sample coating to meet predefined criteria. This may trigger production of the adjusted sample coating material according to the adjusted sample coating formulation used to determine the color data. The produced adjusted sample coating material may be filled into packaging units used to transport the material to a customer.

In an embodiment, determining a second adjusted sample coating formulation includes
providing a method configured to adjust the concentration of at least one individual color component present in the first adjusted sample coating formulation by minimizing a given cost function starting from the concentrations of the individual color components contained in the provided first adjusted sample coating data, and
modifying the concentration of at least one individual color component present in the first adjusted sample coating formulation using the provided method by comparing the color data recursively predicted by the color prediction model using the first adjusted sample coating formulation recursively modified by the method with the provided color data of the reference coating until the color difference falls below a given threshold value or until the number of iterations reaches a predefined limit.

The first adjusted sample coating may correspond to the adjusted sample coating mentioned previously. The first adjusted sample coating is associated with or related to a sample coating. The relationship between the sample coating and the first adjusted sample coating may arise from the fact that the first adjusted sample coating formulation associated with the first adjusted sample coating is obtained by modifying the sample coating formulation associated with the sample coating. The second adjusted sample coating may correspond to an adjusted sample coating obtained after modifying the adjusted sample coating formulation, for example by modifying the component(s) and/or amounts of component(s) of the adjusted sample coating formulation.

The provided data may correspond to the data provided via the communication interface to the at least one computer processor prior to determining the second adjusted sample coating formulation

The method configured to adjust the concentration of at least one individual color component present in the first adjusted sample coating may be selected from the Levenberg-Marquardt algorithm (called LMA or LM), also known as the damped least-squares (DLS) method. The method may be stored on a data storage medium, such as an internal memory of a computing device comprising the at least one processor or in a database connected via the communication interface to the at least one processor. The at least one processor may retrieve the method from the data storage medium upon determining the second adjusted sample coating formulation.

The color difference between the measured color data of sample coating and the predicted color data of the sample coating may be considered during the adjustment of the concentration of at least one individual color component as a constant. This allows to consider the remaining systematic error of the color prediction model, thus increasing the accuracy of the calculation of the second adjusted sample coating formulation.

The cost function may be a color difference between the predicted color data of the recursively modified first adjusted sample coating and the provided color data of the reference coating. Said color difference may be calculated using a color tolerance equation described previously. In case the cost function is a color difference, the given threshold value may be preferably a given or predefined color difference.

The color data may be recursively predicted by the provided physical model using as input data the provided color difference, the provided optical data of individual color components, the provided condition adaption parameters, the provided correction term and the recursively modified first adjusted sample coating formulation. The color difference and the correction term may be added as systematical error of the color prediction model to the preliminary color data predicted by the color prediction model based on the optical data of individual color components, the condition adaption parameters and the recursively modified first adjusted sample coating formulation. The provided physical model may predict the color data, such as reflectance data, of the first adjusted sample coating formulation or the recursively modified first adjusted sample coating formulation based on the input parameters. This prediction may be performed for each modification of the first adjusted sample coating formulation until the cost function falls below a given threshold value or the maximum limit of iterations is reached.

In an embodiment, providing the determined second adjusted sample coating formulation includes providing said determined formulation, optionally in combination with further data, via the communication interface for display. The provided data may be displayed on the screen of a display device as described previously.

In an embodiment, the computer-implemented method for determining a second adjusted sample coating formulation to match the color of a reference coating being present under a second physical conditions based on color data of a first adjusted sample coating being present under a first physical condition further includes initiating at least one action associated with the determined second adjusted sample coating formulation. The at least one action may be initiated by a user or may be initiated by the at least one processor.

Initiating the at least one action may include providing the second adjusted sample coating formulation to a printing device and/or a data storage medium and/or a mixing equipment. Providing the second adjusted sample coating formulation to a mixing equipment may allow to automatically prepare the second adjusted sample coating material based on the received second adjusted sample coating formulation.

In an embodiment, the apparatus further comprises at least one of:
a display device having a screen,
at least one database comprising at least one of a color prediction model, optical data of individual color components associated with the first physical condition, reference coating data, first adjusted sample coating data, condition adaption parameters associated with the difference between the first and the second physical condition of the first adjusted sample coating, the determined correction term for the color prediction model,
a measuring device configured to measure color data of a sample coating and/or a reference coating being present under a second physical condition,
a measuring device configured to measure color data of the sample coating and/or the adjusted sample coating being present under a first physical condition.

The display device may be connected to the one or more computing nodes of the apparatus via a communication interface. The display device may be configured to display data determined or calculated by the one or more computing nodes of the apparatus. For instance, the display device may be configured to display the correction term determined according to the methods disclosed herein. In another instance, the display device may be configured to display the color data of the adjusted sample coating determined according to methods herein. In yet another instance, the display device may be configured to display the second adjusted sample coating formulation determined with the methods disclosed herein.

The at least one database may be connected to the one or more computing nodes of the apparatus via a communication interface. The measuring device(s) may be connected to the one or more computing nodes of the apparatus via a communication interface.

The measuring device configured to measure color data of the sample coating and/or the adjusted sample coating being present under a first physical condition may include a measurement cell which can be filled with coating material present in a wet state as previously described.

The measuring device configured to measure color data of a sample coating and/or a reference coating being present under a second physical condition may be a multi-angle spectrophotometer as described previously.

### BRIEF DESCRIPTION OF DRAWINGS

These and other features of the present invention are more fully set forth in the following description of exemplary embodiments of the invention. To easily identify the discussion of any particular element or act, the most significant digit or digits in a reference number refer to the figure number in which that element is first introduced. The same reference numbers in the drawings and this disclosure are intended to refer to the same or like elements, components, and/or parts. The description is presented with reference to the accompanying drawings in which:

FIG. 1 illustrates a flow chart of a method for providing a correction term for a color prediction model in accordance with an example embodiment of the present disclosure;

FIG. 2A illustrates a flow chart of an aspect of block 102 of FIG. 1 in accordance with an example embodiment of the present disclosure;

FIG. 2B illustrates a flow chart of an aspect of block 210 of FIG. 2A in accordance with an example embodiment of the present disclosure;

FIGS. 3A, 3B illustrate a flow chart of a further aspect of block 102 of FIG. 1 in accordance with an example embodiment of the present disclosure;

FIG. 3C illustrates a flow chart of an aspect of block 318 of FIG. 3B in accordance with an example embodiment of the present disclosure

FIG. 4A illustrates a flow chart of a method for determining the color of an adjusted sample coating being present under second physical conditions based on color data of the adjusted sample coating being present under first physical conditions in accordance with an example embodiment of the present disclosure;

FIG. 4B illustrates a flow chart of a further aspect of the method of FIG. 4A in accordance with an example embodiment of the present disclosure;

FIG. 5 illustrates a flow chart of a method for determining a second adjusted sample coating formulation to match the color of a reference coating being present under a second physical conditions based on color data of a first adjusted sample coating being present under a first physical condition in accordance with an example embodiment of the present disclosure;

FIG. 6 illustrates a flow chart of an aspect of block 504 of FIG. 5 in accordance with an example embodiment of the present disclosure;

FIG. 7A illustrates a schematic drawing of an aspect of the method of FIG. 4A in accordance with an example embodiment of the present disclosure;

FIG. 7B illustrates a schematic drawing of an aspect of the method of FIG. 5 in accordance with an example embodiment of the present disclosure;

FIG. 8 shows an illustrative type of computing device that can be used to implement any aspect of the features shown in FIGS. 1 to 7B;

FIG. 9 illustrates a client-server-setup in accordance with an example embodiment of the present disclosure;

FIG. 10A illustrates a graph containing measured reflectance spectra of a reference coating present in a dry state, an adjusted sample coating batch present in a liquid state and a dry state as well as the reflectance spectra of said adjusted sample coating batch predicted for the dry state according to a color prediction method known in the state of the art based on color data of the adjusted sample coating batch present in liquid state;

FIG. 10B illustrates a graph containing measured reflectance spectra of the reference coating present in a dry state, the adjusted sample coating batch present in a liquid state and a dry state as well as the reflectance spectra of said adjusted sample coating batch predicted for the dry state according to the color prediction method of example embodiment of the present disclosure;

FIG. 10C illustrates a table containing a comparison of color differences for the color data shown in FIG. 10A and FIG. 10B;

FIG. 11A illustrates a graph containing measured reflectance spectra of a further reference coating present in a dry state and a further adjusted sample coating batch present in a liquid state and a dry state, as well as the reflectance spectra of said adjusted sample coating batch predicted for the dry state according to a color prediction method known in the state of the art based on color data of the adjusted sample coating batch present in liquid state;

FIG. 11B illustrates a graph containing measured reflectance spectra of the further reference coating present in a dry state and the further adjusted sample coating batch present in a liquid state and a dry state, as well as the reflectance spectra of said adjusted sample coating batch predicted for the dry state according to the color prediction method of example embodiment of the present disclosure;

FIG. 11C illustrates a table containing a comparison of color differences for the color data shown in FIG. 11A and FIG. 11B;

FIG. 12A illustrates a graph containing measured reflectance spectra of yet a further reference coating present in a dry state and yet a further adjusted sample coating batch present in a liquid state and a dry state, as well as the reflectance spectra of said adjusted sample coating batch predicted for the dry state according to a color prediction method known in the state of the art based on color data of the adjusted sample coating batch present in liquid state;

FIG. 12B illustrates a graph containing measured reflectance spectra of the further reference coating present in a dry state and the further adjusted sample coating batch present in a liquid state and a dry state, as well as the reflectance spectra of said adjusted sample coating batch predicted for the dry state according to the color prediction method of example embodiment of the present disclosure;

FIG. 12C illustrates a table containing a comparison of color differences for the color data shown in FIG. 12A and FIG. 12B.

### DETAILED DESCRIPTION

The detailed description set forth below is intended as a description of various aspects of the subject-matter and is not intended to represent the only configurations in which the subject-matter may be practiced. The appended drawings are incorporated herein and constitute a part of the detailed description. The detailed description includes specific details for the purpose of providing a thorough understanding of the subject-matter. However, it will be apparent to those skilled in the art that the subject-matter may be practiced without these specific details.

In one case, the illustrated separation of various parts in the figures into distinct units may reflect the use of corresponding distinct physical and tangible parts in an actual implementation. Alternatively, or in addition, any single part illustrated in the figures may be implemented by plural actual physical parts. Alternatively, or in addition, the depiction of any two or more separate parts in the figures may reflect different functions performed by a single actual physical part.

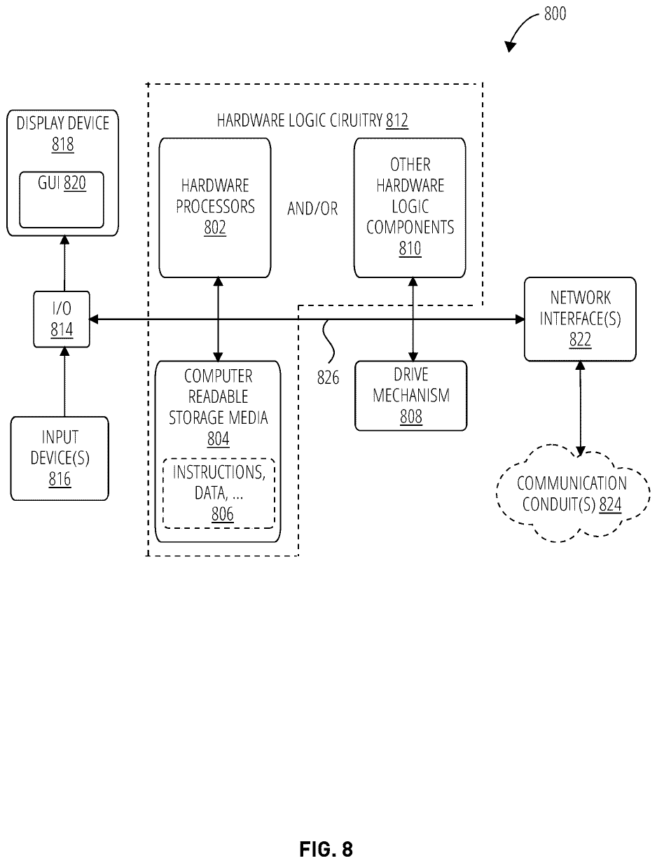

Other figures describe the concepts in flowchart form. In this form, certain operations are described as constituting distinct blocks performed in a certain order. Such implementations are illustrative and non-limiting. Certain blocks described herein can be grouped together and performed in a single operation, certain blocks can be broken apart into plural component blocks, and certain blocks can be performed in an order that differs from that which is illustrated herein (including a parallel manner of performing the blocks). In one implementation, the blocks shown in the flowcharts that pertain to processing-related functions can be implemented by the hardware logic circuitry described in relation to FIG. 8, which, in turn, can be implemented by one or more Hardware processors and/or other logic components that include a task-specific collection of logic gates.

As to terminology, the phrase “configured to” encompasses various physical and tangible mechanisms for performing an identified operation. The mechanisms can be configured to perform an operation using the hardware logic circuitry described in relation to FIG. 8. The term “logic” likewise encompasses various physical and tangible mechanisms for performing a task. For instance, each processing-related operation illustrated in the flowcharts corresponds to a logic component for performing that operation. A logic component can perform its operation using the hardware logic circuitry as described in relation to FIG. 8. When implemented by computing equipment, a logic component represents an electrical component that is a physical part of the computing system, in whatever manner implemented.

The following explanation may identify one or more features as “optional.” This type of statement is not to be interpreted as an exhaustive indication of features that may be considered optional; that is, other features can be considered as optional, although not explicitly identified in the text. Further, any description of a single entity is not intended to preclude the use of plural such entities; similarly, a description of plural entities is not intended to preclude the use of a single entity. Further, while the description may explain certain features as alternative ways of carrying out identified functions or implementing identified mechanisms, the features can also be combined together in any combination. Finally, the terms “exemplary” or “illustrative” refer to one implementation among potentially many implementations.

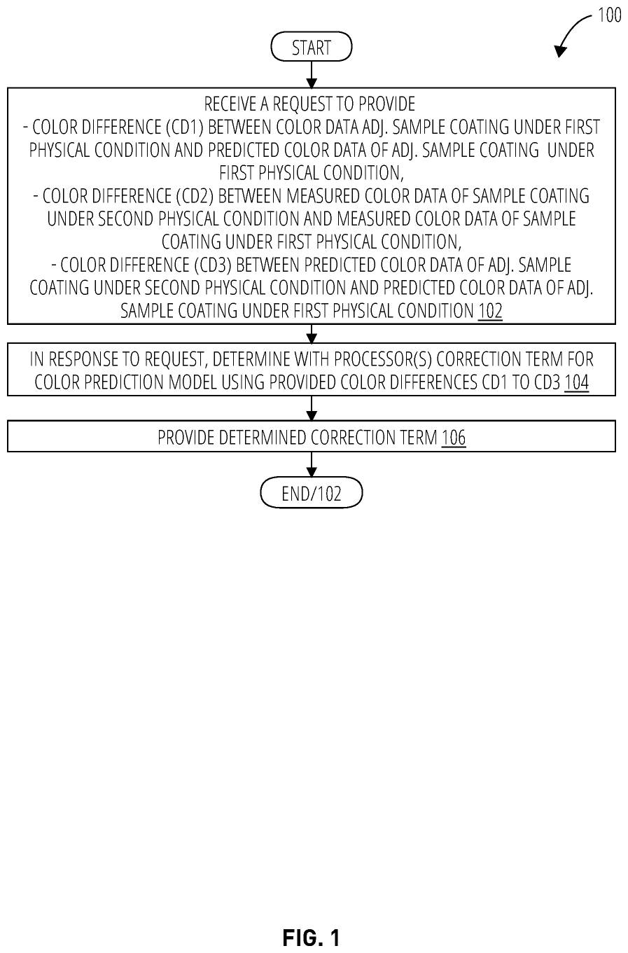

FIG. 1 depicts an example of a method 100 for determining a correction term for a color prediction model, said correction term being associated with an adjusted sample coating being present under at least two different physical conditions. The correction term may be used to transform the systematical error of the color prediction model from a first condition of the adjusted sample coating to a second condition of the adjusted sample coating. The correction term may be considered upon prediction of color data by said color prediction model by adding said correction term to the color data predicted by said color prediction model. This allows to predict color data of the adjusted sample coating being present under a second physical condition more accurately if input data for the color prediction model of the adjusted sample coating being present under first physical condition is used. The first physical condition may be a wet state. The second physical condition may be a dry state. The adjusted sample coating may be associated with an adjusted sample coating material which may be used to prepare the adjusted sample coating. The adjusted sample coating material may be associated with an adjusted sample coating formulation. The adjusted sample coating formulation may be obtained by modifying a sample coating formulation at least once. For instance, the adjusted sample coating formulation may be obtained using commonly known color matching operations, for example using methods described in Georg Klein, Farbenphysik für industrielle Anwendungen mentioned previously, using the sample coating formulation as well as color data of a reference coating as input data. The sample coating material may correspond to a batch of a coating material being prepared according to a defined recipe of formulation.

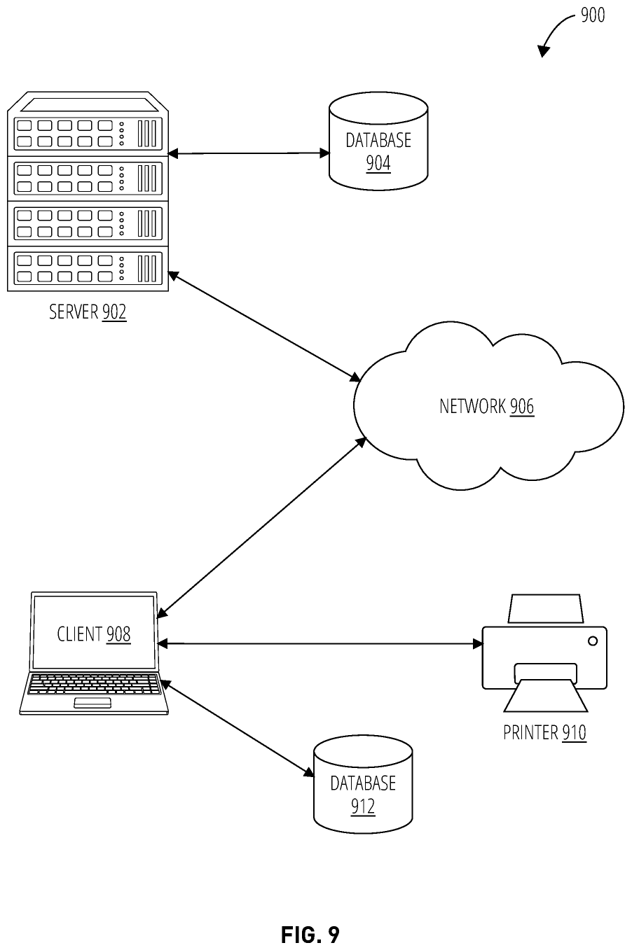

The method 100 may be performed by a computing system, for example a system described in relation to FIG. 8, or may be performed by server 902 of the client-server setup described in relation to FIG. 9.

In block 102, the computing system implementing method 100 may receive a request to provide the following data:
a color difference (CD1) between the measured color data of the adjusted sample coating being present under a first physical condition and the predicted color data of the adjusted sample coating being present under the first physical condition,
a color difference (CD2) between the measured color data of a sample coating being present under the second physical condition and the measured color data of the sample coating being present under the first physical condition, said sample coating being associated with the adjusted sample coating, and
a color difference (CD3) between the predicted color data of the adjusted sample coating being present under the second physical condition and the predicted color data of the adjusted sample coating being present under the first physical condition.

The request may contain data being indicative on initiating method 100, i.e. of determining the correction term, and the computing system may be configured to provide, in response to the request, the above-mentioned data. The request may be received by the computing system from an input/output device, such as a I/O device 814 of FIG. 8 or client 908 of FIG. 9.

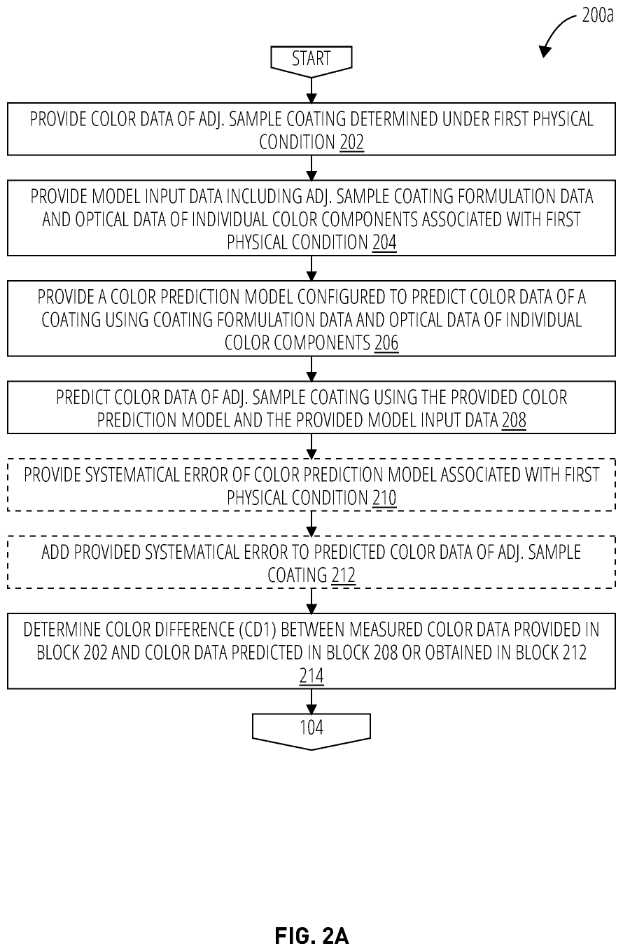

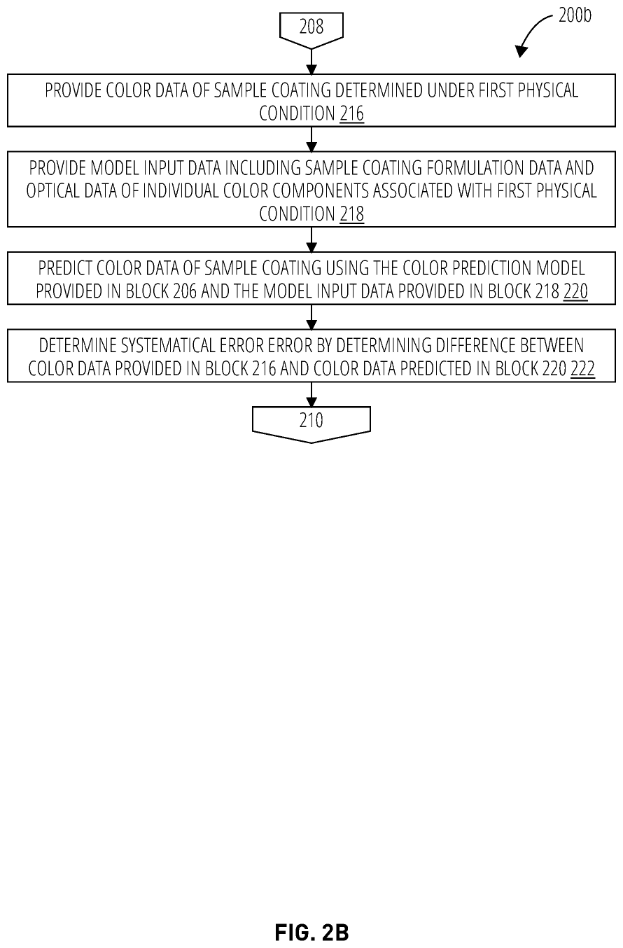

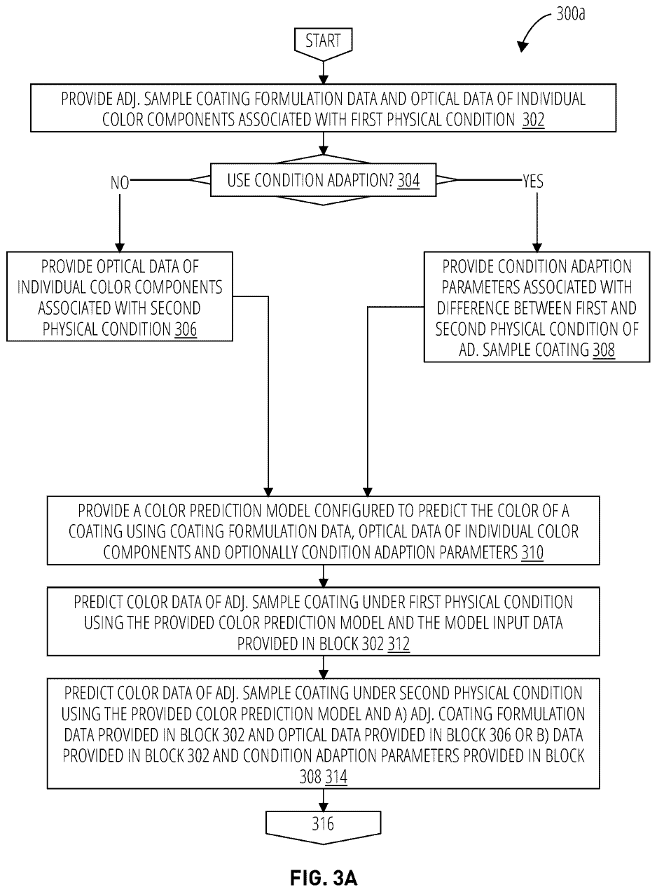

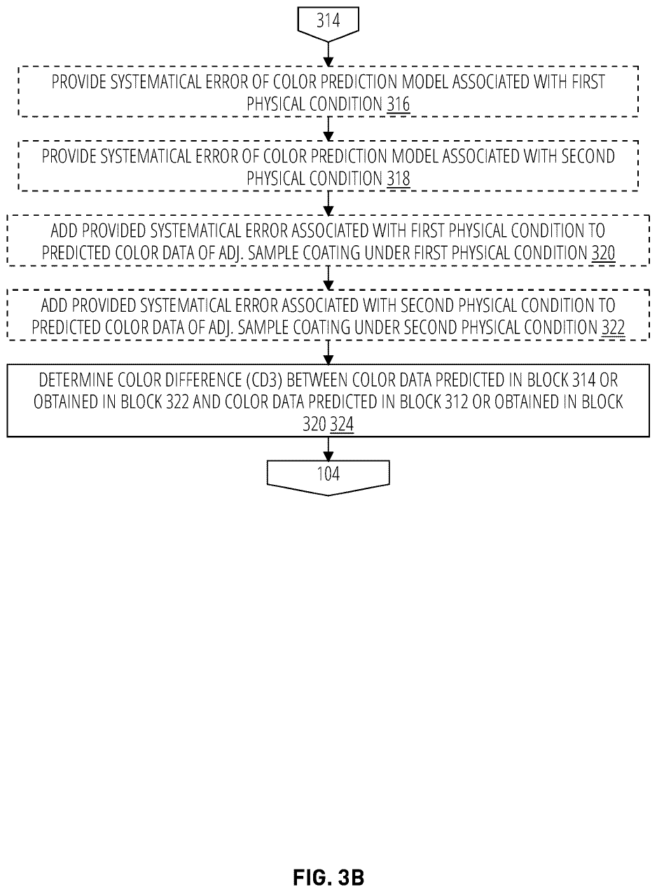

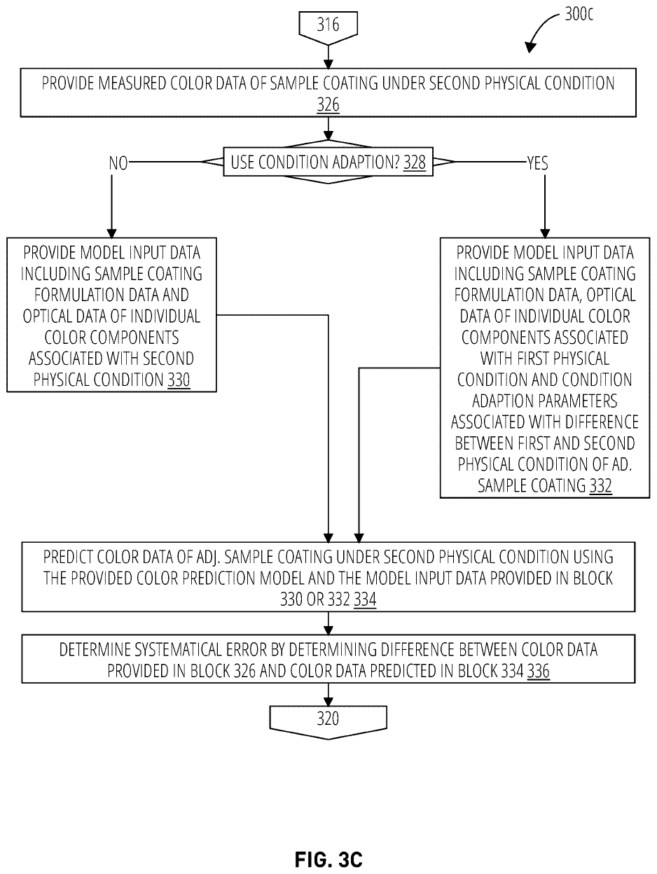

The computing system may be configured to determine the color difference (CD1), for example as described in relation to FIG. 2A. The computing system may be configured to determine the color difference (CD2) by calculating said color difference from provided color data. The color data necessary to calculate the color difference (CD2) may be provided to the computing system via a communication interface. The color data necessary to calculate the color difference (CD2) may be retrieved by computing system based on a received identifier associated with the sample coating. The computing system may be configured to determine the color difference (CD3), for example as described in relation to FIGS. 3A and 3B.

In block 104, the computing system implementing method 100 may determine, in response to the received request, the correction term for the color prediction model using the color differences provided in block 102. The correction term may be determined according to formula (I) and (la) described previously. The correction term may consider the systematical error of the color prediction model upon prediction of color data using input data, such as input data previously described. The correction term may consider the difference in color data between different physical conditions.

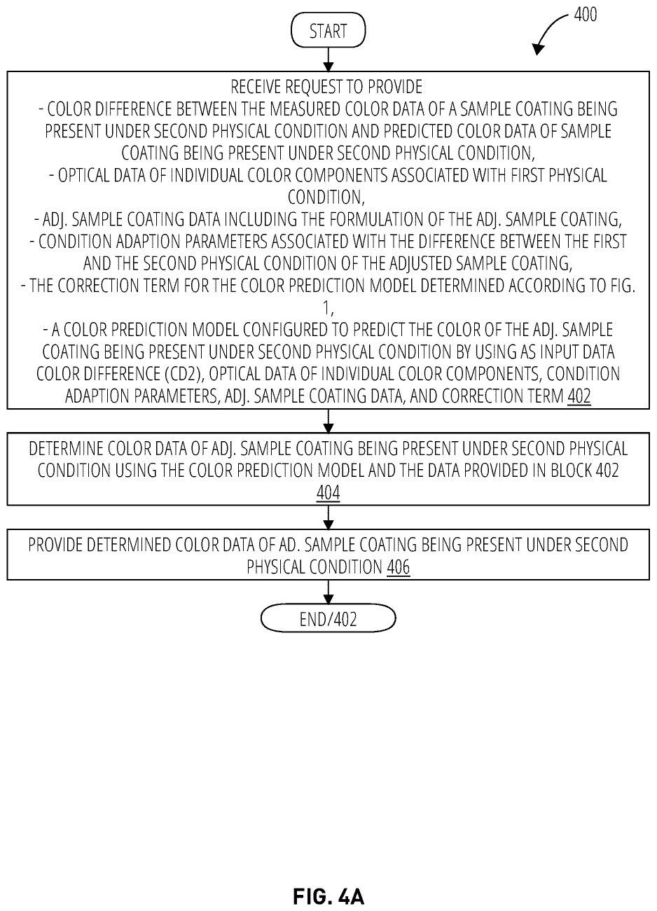

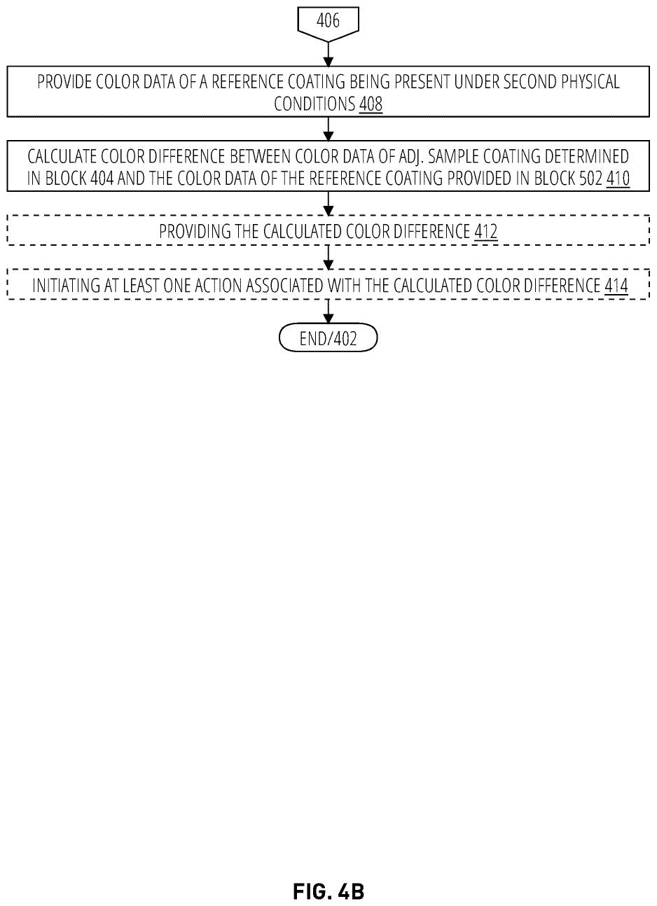

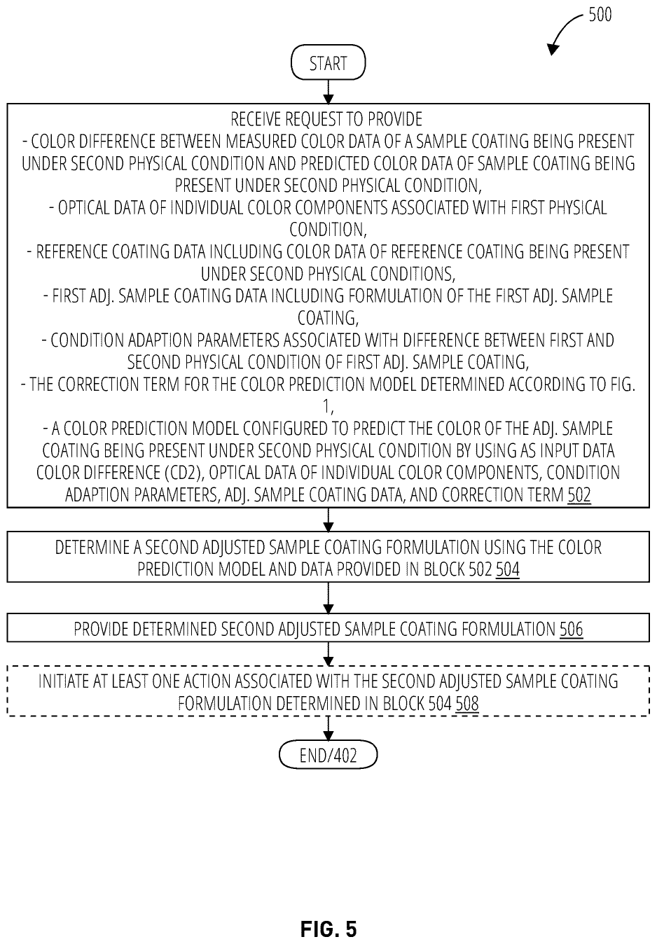

In block 106, the computing system may provide the determined correction term via a communication interface. For instance, the computing system may provide the determined correction term to an I/O device having a display for display. In another instance, the computing system may provide the determined correction term to a data storage medium, for example if said correction term is to be used in a color prediction or color adjustment method described in relation to FIGS. 4A and 5 later on.

FIG. 2A illustrates an example method 200a of providing a color difference (CD1), for example the color difference (CD1) mentioned in relation to block 102 of FIG. 1 above, between the measured color data of the adjusted sample coating being present under a first physical condition and the predicted color data of the adjusted sample coating being present under the first physical condition. The method 200a may be performed by a computing system, for example the computing system implementing method 100 described in relation to FIG. 1.

In block 202, color data of the adjusted sample coating determined under the first physical condition may be provided. The first physical condition may be a wet state. The color data may be determined using a suitable measurement device, such as a multi-angle spectrophotometer being configured to determine color data of a liquid coating material being present within a measurement cell. The acquired data may be used to determine the respective color data. For instance, the acquired reflectance data may be used to determine color space data as described previously. The color data may be determined by the computing system controlling the measurement device or by the computing system implementing method 200a. The determined color data may be retrieved from a data storage medium by the computing system implanting method 200a. For instance, the computing system may receive data being indicative of the adjusted sample coating, such as an ID, and may retrieve said color data based on the received data.

In block 204, model input data may be provided. The model input data may include adjusted sample coating formulation data and optical data of individual color components. Said optical data may be associated with the first physical condition. The adjusted sample coating formulation data may include data on the components and their respective amounts being present in the adjusted sample coating material used to prepare the adjusted sample coating. The optical data may be stored on a data storage medium and may be retrieved by the computing system based on the adjusted sample coating formulation data. For instance, the computing system may be configured to determine the components present in the adjusted sample coating material from the formulation data and may retrieve optical data associated with the determined components from the data storage medium.

In block 206, a color prediction model configured to predict color data of a coating using coating formulation data and optical data of individual color components may be provided. The color prediction model may be stored on a data storage medium and may be retrieved by the computing system.

In block 208, color data of the adjusted sample coating may be determined using the model provided in block 206 and the model input data provided in block 204. The color prediction model may use the formulation data as well as the optical data associated with components present within the adjusted sample coating material to predict color data associated with the adjusted sample coating material. The predicted color data may be associated with the first physical condition since the optical data used for the color prediction is also associated with the first physical condition.

In block 210, the systematical error of the color prediction model associated with the first physical condition may be provided, this block being generally optional. The systematical error associated with the first physical condition may be determined as described in relation to FIG. 2B later on. Providing the systematical error may include retrieving said error from a data storage medium.

In block 212, the systematical error provided in block 210 may be added to the color data of the adjusted sample coating predicted in block 208, this block being generally optional. Use of the systematical error may improve the accuracy of the correction term and thus also the accuracy of color prediction or color matching methods using said correction term.

In block 214, the color difference (CD1) between the color data provided in block 202 and the color data predicted in block 208 or the color data obtained in block 212 may be determined. Method 200a may then proceed to block 104 of method 100 described in relation to FIG. 1

FIG. 2B illustrates an example method 200b of providing a systematical error of the color prediction model mentioned in relation to block 210 of FIG. 2A above. The method 200b may be performed by a computing system, for example the computing system implementing method 100 described in relation to FIG. 1.

In block 216, color data of a sample coating determined under the first physical condition may be provided. The sample coating may be associated with the adjusted sample coating. For instance, the adjusted sample coating may be obtained by modifying the sample coating, for example by modifying at least one compound and/or the amount of at least one compound present in the sample coating formulation to obtain an adjusted sample coating formulation. The sample coating may correspond to a batch of coating material produced according to a given recipe or formulation. The sample coating material may be a liquid sample coating material. The color data may be determined as described in relation with block 202 of FIG. 2A.

In block 218, model input data may be provided. The model input data may include sample coating formulation data and optical data of individual color components. Said optical data may be associated with the first physical condition. The sample coating formulation data may include data on the components and their respective amounts being present in the sample coating material used to prepare the sample coating. The optical data may be stored on a data storage medium and may be retrieved as described in relation to block 204 of FIG. 2A.

In block 220, the color data of the sample coating may be determined using the color prediction model provided in block 206 of FIG. 2A as well as the model input data provided in block 218. Prediction of the color data may be performed as described in relation to block 208 of FIG. 2A.

In block 222, the systematical error of the color prediction model may be determined by determining the difference between the color data provided in block 216 and the color data predicted in block 222. The difference may be determined as described in relation to block 214 of FIG. 2A. The systematical error determined in block 222 may be used in block 212 of FIG. 2A. Use of said systematical error allows to improve the accuracy of the determined correction term and thus also the accuracy of color prediction and color matching methods using said correction term.

FIGS. 3A and 3B illustrate an example method 300a of providing a color difference (CD3), for example the color difference (CD3) mentioned in relation to block 102 of FIG. 1 above, between the predicted color data of the adjusted sample coating under the second physical condition and the predicted color data of the adjusted sample coating under the first physical condition. The method 300a may be performed by a computing system, for example the computing system implementing method 100 described in relation to FIG. 1.

In block 302, adjusted sample coating formulation data and optical data associated with the first physical condition may be provided. Said data may be provided, for example, as described in relation to block 204 of FIG. 2A.

In block 304, the use of condition adaption may be determined. This may be performed based on the physical condition the available optical data is associated with. The available optical data may be stored on a data storage medium. The computing system implementing method 300a may be configured to determine the physical condition the available optical data is associated with. For instance, if the available optical data is associated with the second physical condition, no condition adaption is required and method 300a proceeds to block 306. Otherwise, i.e. if the available optical data is only associated with the first physical condition, condition adaption is required and method 300a proceeds to block 308.

In block 306, optical data of individual color components associated with the second physical condition may be provided. This may be performed, for example, as described in relation to block 202 of FIG. 2A.

In block 308, condition adaption parameters associated with the difference between the first and the second physical condition of the adjusted sample may be provided. The condition adaptation parameters may be determined, for example, by the computing system implementing method 300a. The condition adaption parameters may be pre-configured and/or may be determined using an optimization method and the color prediction model. The optimization method may be configured to optimize condition adaption parameters by minimizing a cost function starting from a set of initial condition adaption parameters. The color prediction model may predict the color data of the adjusted sample coating using the condition adaption parameters optimized by the optimization method. The cost function may be a color difference between the color data predicted by the color prediction model for the sample coating being present under the second physical conditions and the measured color data of the sample coating being present under the second physical conditions. The optimization method may optimize the condition adaption parameters until the color difference falls below a given threshold value. The condition adaption parameters determined using input data associated with the sample coating may correspond to condition adaption parameters associated with the adjusted sample coating, i.e. the condition adaption parameters determined using input data associated with the sample coating may be used for the adjusted sample coating without resulting in a significant error. This allows to determine the condition adaption parameters required to account for the use of optical data associated with the first physical condition when predicting the color data of the adjusted sample coating being present under a second physical condition. The determined condition adaption parameters may be stored on a data storage medium. The determined condition adaption parameters may be provided as input data to the color prediction model.

In block 310, a color prediction model may be provided, for example as described in relation to block 206 of FIG. 2A. The color prediction model may be configured to predict the color of the adjusted sample coating using adjusted sample coating formulation data, optical data of individual color components and optionally condition adaption parameters as input data.

In block 312, the color data of the adjusted sample coating being present under the first physical condition may be determined using the color prediction model provided in block 310 and the model input data provided in block 302. The color data may be predicted as described in in relation to block 208 of FIG. 2A.

In block 314, the color data of the adjusted sample coating being present under the second physical condition may be determined using the color prediction model provided in block 310, the adjusted sample coating formulation provided in block 302 and the optical data provided in block 306. The color data of the adjusted sample coating being present under the second physical condition may be predicted using the color prediction model provided in block 310, the data provided in block 302 and the condition adaption parameters provided in block 308. The condition adaption parameters may be considered by adding said parameters as systematical error to the color data predicted by the color prediction model. The color data may be predicted as described in in relation to block 208 of FIG. 2A.

In block 316 (see FIG. 3B), the systematical error of the color prediction model associated with the first physical condition may be provided, this block being generally optional. Said error may be provided as described in relation to FIG. 2B. Use of the systematical error may improve the accuracy of the correction term and thus also the accuracy of color prediction or color matching methods using said correction term.

In block 318 (see FIG. 3B), the systematical error of the color prediction model associated with the second physical condition may be provided, this block being generally optional. Said error may be provided as described in relation to FIG. 3C later on. Use of the systematical error may improve the accuracy of the correction term and thus also the accuracy of color prediction or color matching methods using said correction term.

In block 320 (see FIG. 3B), the systematical error provided in block 316 may be added to the color data of the adjusted sample coating predicted in block 312, this block being generally optional.

In block 322 (see FIG. 3B), the systematical error provided in block 318 may be added to the color data of the adjusted sample coating predicted in block 314, this block being generally optional.

In block 324, the color difference (CD3) between the color data predicted in block 314 and the color data predicted in block 312 may be determined. The color difference (CD3) between the color data obtained in block 322 and the color data obtained in block 320 may be determined. The latter may be performed if the systematical error is to be considered. Considering said systematical error allows to improve the accuracy of the correction term and thus also the accuracy of the color prediction and color matching operations using said correction term as previously described.

FIG. 3C illustrates an example method 300c of providing a systematical error of the color prediction model mentioned in relation to block 318 of FIG. 3B above. The method 300c may be performed by a computing system, for example the computing system implementing method 300a described in relation to FIG. 3A.

In block 326, color data of a sample coating determined under the second physical condition may be provided. The sample coating may be associated with the adjusted sample coating as described in relation to FIG. 2B. The color data may be determined as described in relation with block 202 of FIG. 2A.

In block 328, the use of condition adaption may be determined. This may be performed based on the result of the determination performed in block 304 described in relation to FIG. 3A. If no condition adaption is to be used, method 300c may proceed to block 330. Otherwise, method 300c may proceed to block 332 described later on

In block 330, model input data may be provided. The model input data may include sample coating formulation data and optical data of individual color components. Said optical data may be associated with the second physical condition. The optical data may be provided as described in relation to block 306 of FIG. 3A.

In block 332, model input data may be provided. The model input data may include sample coating formulation data, optical data of individual color components and condition adaption parameters associated with the difference between the first and the second physical condition of the adjusted sample coating. The optical data is associated with the first physical condition. The condition adaption parameters may be provided as described in relation to block 308 of FIG. 3A.

In block 334, the color data of the sample coating may be determined using the color prediction model provided in block 310 of FIG. 3A as well as the model input data provided in block 330 or provided in block 332. Prediction of the color data may be performed as described in relation to block 208 of FIG. 2A.

In block 336, the systematical error of the color prediction model may be determined by determining the difference between the color data provided in block 326 and the color data predicted in block 334. The difference may be determined as described in relation to block 214 of FIG. 2A. The systematical error determined in block 336 may be used in block 318 of FIG. 3B. Use of said systematical error allows to improve the accuracy of the determined correction term and thus also the accuracy of color prediction and color matching methods using said correction term.

FIG. 4A depicts an example of a method 400 for determining color data of an adjusted sample coating being present under second physical conditions based on color data of the adjusted sample coating being present under first physical conditions. The first physical condition may be a wet state. The second physical condition may be a dry state. The method may use a correction term, such as the correction term determined as described in relation to FIGS. 1 to 3C above. The correction term allows to transform the systematical error of the color prediction model from a first condition of the adjusted sample coating to a second condition of the adjusted sample coating. This results in a more accurate determination of the color data of the adjusted sample coating being present under a second physical condition using input data for the color prediction model of the adjusted sample coating being present under first physical condition. The correction term may be considered by adding said correction term to the color data predicted by the color prediction model.

The method 400 may be performed by a computing system, for example a system described in relation to FIG. 8, or may be performed by server 902 of the client-server setup described in relation to FIG. 9.

In block 402, the computing system implementing method 400 may receive a request to provide the following data:
a color difference between the measured color data of a sample coating being present under the second physical condition and the predicted color data of the sample coating being present under the second physical condition,
optical data of individual color components associated with the first physical condition,
adjusted sample coating data including the formulation of the adjusted sample coating,
condition adaption parameters associated with the difference between the first and the second physical condition of the adjusted sample coating,
a correction term for the color prediction model determined according to methods disclosed herein, for example the methods described in relation to FIGS. 1 to 3C above, and
a color prediction model configured to predict the color of the adjusted sample coating being present under the second physical condition by using as input data the color difference, the optical data of individual color components, the condition adaption parameters, the adjusted sample coating data, and the correction term.

The sample coating is associated with the adjusted sample coating. For instance, the adjusted sample coating may be obtained by modifying the sample coating formulation associated with the sample coating at least once as previously described. The sample coating material associated with the sample coating may correspond to a batch of a coating material being prepared according to a defined recipe of formulation.

The request may contain data being indicative on initiating method 400, i.e. of determining the color data of the adjusted sample coating being present under the second physical condition, and the computing system may be configured to provide or retrieve, in response to the request, the above-mentioned data. The request may be received by the computing system from an input/output device, such as a I/O device 814 of FIG. 8 or client 908 of FIG. 9.

The computing system may be configured to determine the color difference between the measured color data of a sample coating being present under the second physical condition and the predicted color data of the sample coating being present under the second physical condition, for example as described in relation to FIG. 3C. The computing system may be configured to determine the condition adaption parameters, for example as described in relation to FIG. 3A.

In block 404, the computing system implementing method 400 may determine, in response to the received request, color data of the adjusted sample coating being present under the second physical condition using the data provided in block 402 as previously described. The color prediction model may be configured to predict the color of the adjusted sample coating by
predicting color data of the adjusted sample coating based on the optical data of individual color components and the adjusted sample coating data and
adding the color difference, the condition adaption parameters and the correction term to the predicted color data.

The color difference, the condition adaption parameters and the correction term may relate to systematical errors of the color prediction model associated with the prediction of the color of the adjusted sample coating being present under second physical conditions based on color data of the adjusted sample coating being present under first physical conditions. Such systematical errors may be added to the color (e.g. color data) predicted by the physical model based on the formulation of the adjusted sample coating and the optical data of individual color components.

In block 406, the computing system may provide the determined color data via a communication interface. For instance, the computing system may provide the determined color data to an I/O device having a display for display. In another instance, the computing system may provide the determined color to a data storage medium, for example if said color data is to be used later on. This may include interrelating said color data with an adjusted sample coating identifier to allow retrieval of said color data using the identifier. After the end of block 406, the routine implementing method 400 may return to block 402 or may end method 400.

FIG. 4B illustrates an example of a further aspect of the method described in relation to FIG. 4A. The steps illustrated in FIG. 4B may be performed in addition to the steps described in relation to FIG. 4A. The steps of FIG. 4B may allow to compare the determined color data to color data of a reference coating, thus allowing to determine the degree of color matching between the adjusted sample coating and the reference coating. The method described in FIG. 4B may be implemented using a computing system, such as a computing system described in relation to FIG. 4A. For instance, the method of FIG. 4B may be performed with the computing system performing method 400 described in relation to FIG. 4A.

In block 408, color data of a reference coating being present under the second physical condition may be provided. The color data may be provided from a data storage medium, such as a database. For instance, the computing system may receive data being indicative of the reference coating, such as an ID, and may retrieve the color data using said received data. In another instance, the computing system may use data being indicative of the adjusted sample coating to retrieve the color data of the reference coating associated with said adjusted sample coating.

In block 410, a color difference between the color data of the adjusted sample coating determined in block 404 of FIG. 4A and the color data of the reference coating provided in block 408 may be calculated. The color difference may be calculated using one of the afore-mentioned color tolerance equations.

In block 412, the calculated color difference may be provided, this block being generally optional. For instance, the color difference may be provided via a communication interface to a display device for display, such as described in relation to block 406 of FIG. 4A.

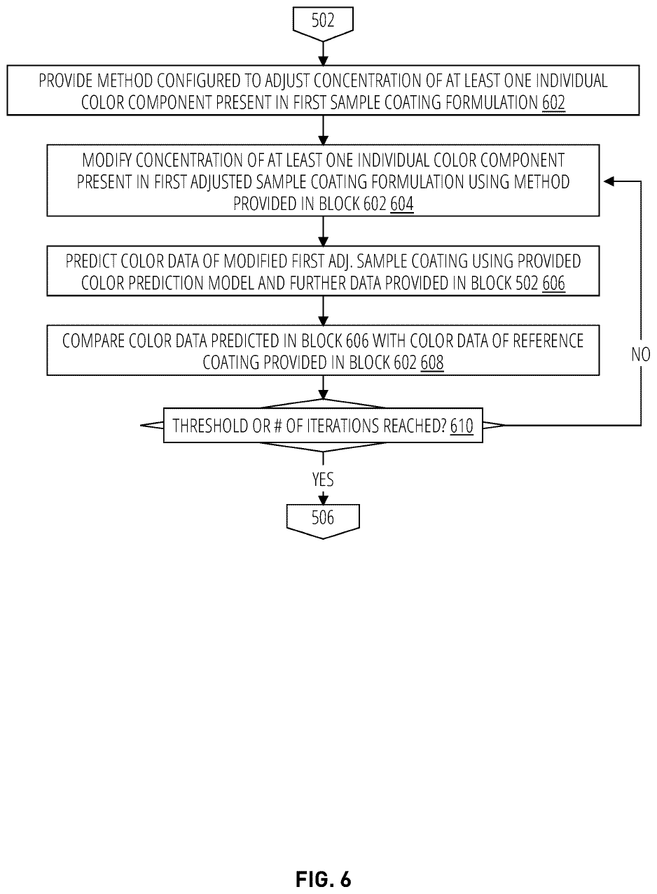

In block 414, at least one action associated with the calculated color difference may be initiated, this block being generally optional. The at least one action may be associated with the determined color difference being above or below a defined threshold value. The threshold value may be a predefined color difference. For instance, the computing system may initiate calculation of a further adjusted sample coating formulation, for example as described in relation to FIGS. 5 and 6, if the determined color difference is above the predefined threshold value, i.e. if there is no sufficient color match between the color of the adjusted sample coating and the color of the reference coating. In another instance, the computing system may initiate providing the adjusted sample coating formulation to a printing device and/or a data storage medium and/or a filling line. After the end of block 414, the method may be ended, or the method may return to block 402.

FIG. 5 depicts an example of a method 500 for determining a second adjusted sample coating formulation to match the color of a reference coating being present under a second physical conditions based on color data of a first adjusted sample coating being present under a first physical condition. The first physical condition may be a wet state. The second physical condition may be a dry state. The second adjusted sample coating formulation may be obtained by modifying the first adjusted sample coating formulation at least once. The first adjusted sample coating formulation may correspond to the adjusted sample coating formulation described in relation to FIGS. 1 to 4B above. The method may use a correction term, such as the correction term determined as described in relation to FIGS. 1 to 3C above. The correction term allows to transform the systematical error of the color prediction model from a first condition of the adjusted sample coating to a second condition of the adjusted sample coating. This results in a more accurate determination of the color data of the adjusted sample coating being present under a second physical condition using input data for the color prediction model of the adjusted sample coating being present under first physical condition.

The method 500 may be performed by a computing system, for example a system described in relation to FIG. 8, or may be performed by server 902 of the client-server setup described in relation to FIG. 9.

In block 502, the computing system implementing method 500 may receive a request to provide the following data:
a color difference between the measured color data of a sample coating being present under the second physical condition and the predicted color data of the sample coating being present under the second physical condition, said sample coating being associated with the first adjusted sample coating,
optical data of individual color components associated with the first physical condition,
reference coating data including color data of the reference coating being present under the second physical conditions,
first adjusted sample coating data including the formulation of the first adjusted sample coating,
condition adaption parameters associated with the difference between the first and the second physical condition of the first adjusted sample coating,
a correction term for the color prediction model determined according to methods disclosed herein, for example the methods described in relation to FIGS. 1 to 3C above,
a color prediction model configured to predict the color of the second adjusted sample coating being present under the second physical condition by using as input data the color difference, the optical data of individual color components, the reference coating data, the first adjusted sample coating data, the condition adaption parameters, and the correction term.

The sample coating is associated with the first adjusted sample coating. For instance, the first adjusted sample coating may be obtained by modifying the sample coating formulation associated with the sample coating at least once as previously described. The sample coating material associated with the sample coating may correspond to a batch of a coating material being prepared according to a defined recipe of formulation.

The request may contain data being indicative on initiating method 500, i.e. of determining the color data of the adjusted sample coating being present under the second physical condition, and the computing system may be configured to provide or retrieve, in response to the request, the above-mentioned data. The request may be received by the computing system from an input/output device, such as a I/O device 814 of FIG. 8 or client 908 of FIG. 9.

The computing system may be configured to determine the color difference between the measured color data of a sample coating being present under the second physical condition and the predicted color data of the sample coating being present under the second physical condition, for example as described in relation to FIG. 3C. The computing system may be configured to determine the condition adaption parameters, for example as described in relation to FIG. 3A.

In block 504, a second adjusted sample coating formulation may be determined using the color prediction model and the further data provided in block 402. The second adjusted sample coating formulation may be determined as described in relation to FIG. 6.

In block 506, the determined second adjusted sample coating may be provided via a communication interface. For instance, the computing system may provide the determined formulation to an I/O device having a display for display. In another instance, the computing system may provide the determined formulation to a data storage medium, for example if said formulation is to be used in later on.

In block 508, at least one action associated with the second adjusted sample coating formulation determined in block 504 may be initiated, this block being generally optional. Initiating the at least one action may include providing the second adjusted sample coating formulation to a printing device and/or a data storage medium and/or a mixing equipment. After the end of block 508, method 500 may return to block 502 or may end.

FIG. 6 illustrates a flow chart of an aspect of block 504 of FIG. 5 in accordance with an example embodiment of the present disclosure. The method described in FIG. 6 may be performed by the computing system implementing method 500 of FIG. 5.

In block 602, a method configured to adjust the concentration of at least one individual color component present in the first adjusted sample coating formulation is provided. A suitable method may include the Levenberg-Marquardt algorithm (called LMA or LM), also known as the damped least-squares (DLS) method. Adjustment of the concentration may be performed by minimizing a given cost function starting from the concentrations of the individual color components contained in the first adjusted sample coating data provided in block 502 of FIG. 5. The cost function may be a color difference between the predicted color data of the recursively modified first adjusted sample coating and the provided color data of the reference coating. Said color difference may be calculated using a color tolerance equation described previously.

In block 604, the concentration of at least one individual color component present in the first adjusted sample coating formulation may be modified using the method provided in block 602.

In block 606, color data of the modified first adjusted sample coating formulation resulting after performing block 604 may be determined using the color prediction model, the color difference, the optical data of individual color components, the condition adaption parameters and the correction term provided in block 502 of FIG. 5. Color data may be predicted by the color prediction model using the optical data of individual color components and the modified adjusted sample coating formulation. The color difference, condition adaption parameters and the correction term may be added as systematical error of the color prediction model to the color data predicted by the color prediction model based on the optical data of individual color components and the recursively modified first adjusted sample coating formulation.

In block 608, the color data determined in block 606 may be compared with the color data of the reference coating provided in block 602. This may include determining a color difference, for example by using a color tolerance equation mentioned previously.

In block 610, it may be determined whether the color difference determined in block 608 has fallen below a predefined threshold value or whether the number of iterations has reached a predefined limit. If the determined color difference has fallen below the predefined threshold value or the limit of iterations has been reached, the method proceeds to block 506 of FIG. 6. Otherwise, the method repeats blocks 604 to 608 described previously.

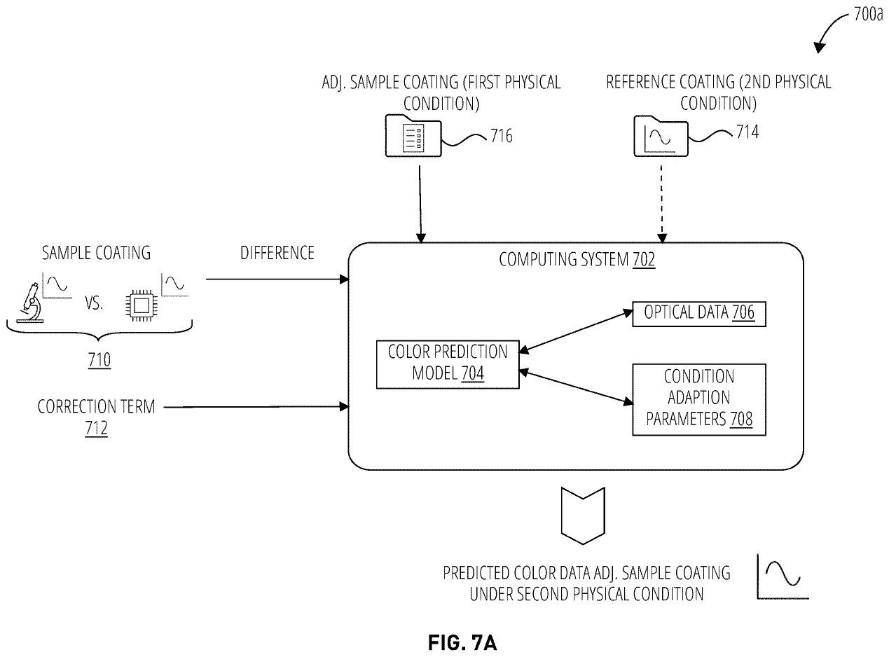

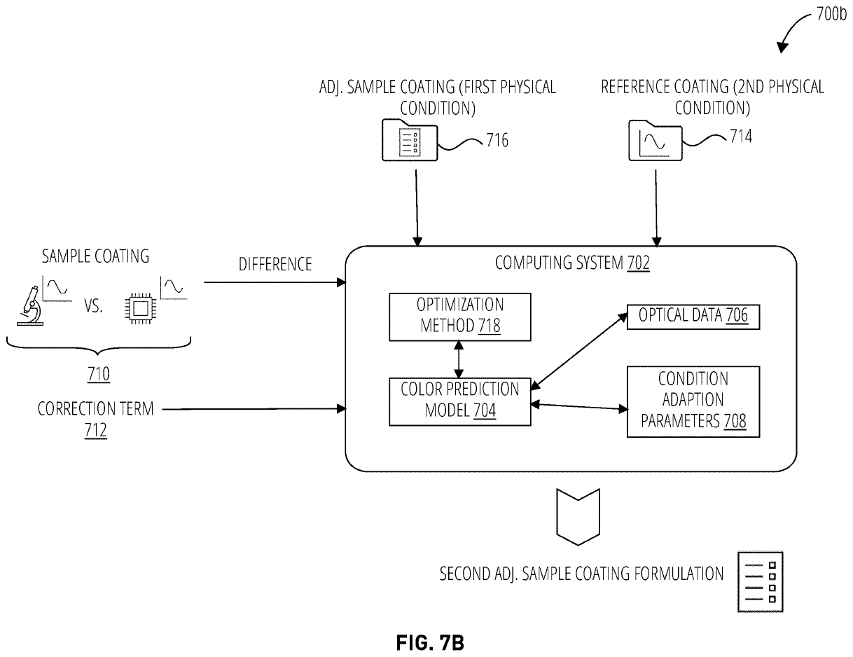

FIG. 7A illustrates a schematical drawing of method 700a determining the color data of an adjusted sample coating being present under second physical conditions based on color data of the adjusted sample coating being present under first physical conditions according to embodiments disclosed herein. The method may be performed using a color prediction model 704, for example a physical model describing the interaction of light with scattering or absorbing media, e.g. with colorants in coating layers. The model may be implemented and running on at least one processor of a computing system 702. The model 704 may have access to optical data of individual color components 706, such as optical data associated with a first physical condition. The optical data may include optical constants of individual color components. Each individual color component may be associated with a set of constants, such as wavelength dependent K and S values. The model 704 may have access to condition adaption parameters 708 associated with the difference between the first and the second physical condition. The condition adaption parameters may be determined using the method described in relation to FIG. 3A.

A color difference 710 between the measured color data of a sample coating being present under the second physical condition and the predicted color data of the sample coating being present under the second physical condition is provided to the computing system 702, for example as previously described in relation to FIG. 4A. In contrast to color prediction methods described in the state of the art, such as described in WO 2022/122777 A1, a correction term 712 reflecting the difference in color data associated with different physical conditions is provided to the computing system 702. The correction term may relate to a systematical error of the color prediction model 704 and may be considered during prediction of the color data by adding said correction term to the color data predicted by the color prediction model 704 based on the optical data 706 and the adjusted sample coating data 716. The correction term may be determined according to the methods disclosed herein, for example as described in relation to FIGS. 1 to 3C. Use of the correction term allows to predict the color data of an adjusted sample coating more accurate compared to methods known in the state of the art, because the correction term allows to consider deviations of the color data associated with different physical conditions. This allows to use input data associated with a first physical conditions and to accurately predict color data associated with a second physical condition. Use of input data associated with a different physical condition than the color data to be predicted may be relevant if color data of the reference coating used as target is only available for a second physical condition while input data is hard to generate for said physical condition. For instance, a produced liquid coating material is tinted in the wet state such that the color data of a coating resulting from said produced liquid coating material matches the color data of a dried and/or cured reference coating. This, however, requires an accurate prediction of the color data of the coating produced from the liquid coating material in order to generate accurate tinting instructions, i.e. in order to determine adjustments resulting in a sufficient color match of the tinted coating vs. the reference coating.

Adjusted sample coating data including the formulation of the adjusted sample coating 716 may be provided to the computing system 702. The adjusted sample coating formulation may be determined, for example, as described in relation to FIG. 4A. Using the adjusted sample coating data, the received color difference as well as the correction term as input data, the color prediction model 704 may predict the color data of the adjusted sample coating using the optical data 706 and the condition adaption parameters 708, for example as described in relation to FIGS. 4A and 4B. The predicted color data of the adjusted sample coating being present under second physical conditions, such as the dry state, is then provided, for example via a communication interface, for display on a screen. If a color difference between the predicted color data and the reference coating is to be determined, color data of a reference coating being present under the second physical condition 714, such as the dry state, may be provided to the computing system 702 and the computing system may be configured to determine a color difference between the predicted color data and the received reference coating color data, for example as described in relation to FIG. 4B. The computing system 702 may be configured to provide the determined color difference. The computing system 702 may be configured to initiate at least one action associated with the calculated color difference (see for example FIG. 4B).

FIG. 7B illustrates a schematical drawing of method 700b for determining a second adjusted sample coating formulation to match the color of a reference coating being present under a second physical conditions based on color data of a first adjusted sample coating being present under a first physical condition. The second adjusted sample coating formulation may be obtained by modifying the first adjusted sample coating formulation provided as input data. The first adjusted sample coating formulation may correspond to the adjusted sample coating formulation described previously. The first adjusted sample coating formulation may be obtained by modifying a sample coating formulation using commonly known color matching operations. The sample coating formulation may correspond to a batch of a sample coating material prepared by mixing various coating material ingredients according to a given recipe or formulation. The method 700b may be performed by a color prediction model 704 and an optimization method 718. The model and optimization method may be implemented and running on at least one processor of a computing system 702. The model 704 may have access to optical data of individual color components 706, such as optical data associated with a first physical condition (see FIG. 7A). The model 704 may have access to condition adaption parameters 708 associated with the difference between the first and the second physical condition. The condition adaption parameters may be determined using the method described in relation to FIG. 3A.

A color difference 710 between the measured color data of a sample coating being present under the second physical condition and the predicted color data of the sample coating being present under the second physical condition may be provided to the computing system 702, for example as previously described in relation to FIG. 7A. Moreover, a correction term 712 reflecting the difference in color data associated with different physical conditions may be provided to the computing system 702. The correction term 712 as well as the color difference 710 may be considered as constants during adjustment of the sample coating formulation using numerical method 718, e.g. may be added to the color data predicted by the color prediction model 704.

Data of the reference coating 714 may be provided to the computing system 702. Said data may include color data, such as reflectance data, of the reference coating prepared from a reference coating formulation. The reference coating may be present in a dry state. The reference coating may be prepared by applying at least the respective reference coating material to a substrate and drying and/or curing said applied coating material.

Adjusted sample coating data including the formulation of the adjusted sample coating 716 may be provided to the computing system 702. The adjusted sample coating formulation may be determined, for example, as described in relation to FIG. 4A.

Using the adjusted sample coating data 716, the received color difference 710 and the correction term 712 as input data, the color prediction model 704 may predict the color data of the adjusted sample coating using the optical data 706 and the condition adaption parameters 708, for example as described in relation to FIGS. 4A and 4B. After determining the color data, optimization method 718 may modify the concentration of at least one colorant present in the adjusted sample coating formulation by minimizing the color difference between the color data of the reference coating and the color data of the recursively modified adjusted sample coating predicted by physical model 704. Upon each modification of the adjusted sample coating formulation by optimization method 718, physical model 704 may be used to predict the color data based on the optical data 706, the condition adaption parameters 708 and the modified adjusted sample coating formulation. The modification may be repeated by optimization method 718 until the color difference between the color data of the reference coating and the predicted color data of the recursively modified adjusted sample coating reaches a given threshold or until a predefined maximum limit of iterations is reached. The second adjusted sample formulation associated with the color difference reaching the given threshold or the second adjusted formulation associated with the maximum number of iterations may then be provided by the computing system 702, for example via a communication interface, for display on a screen. The computing system 702 may be configured to initiate at least one action associated with the calculated color difference (see for example FIG. 4B).

FIG. 8 shows a computing device 800 that can be used to implement any aspect of the mechanisms set forth in the above-described FIGS. 1 to 7B. For instance, with reference to FIGS. 1 to 6, the type of computing device 800 shown in FIG. 8 can be used to implement any computing device associated with the methods disclosed in said figures. In another instance, the type of computing device 800 shown in FIG. 8 can be used to implement any computing device associated with the computing system 702 of FIGS. 7A and 7B. In all cases, the computing device 800 represents a physical and tangible processing mechanism.

The computing device 800 can include one or more hardware processors 802. The hardware processor(s) can include, without limitation, one or more Central Processing Units (CPUs), and/or one or more Graphics Processing Units (GPUs), and/or one or more Application Specific Integrated Circuits (ASICs), etc. More generally, any hardware processor can correspond to a general-purpose processing unit or an application-specific processor unit.

The computing device 800 can also include computer-readable storage media 804, corresponding to one or more computer-readable media hardware units. The computer-readable storage media 804 retains any kind of information 806, such as machine-readable instructions, settings, data, etc. Without limitation, for instance, the computer-readable storage media 804 may include one or more solid-state devices, one or more magnetic hard disks, one or more optical disks, magnetic tape, and so on. Any instance of the computer-readable storage media 804 can use any technology for storing and retrieving information. Further, any instance of the computer-readable storage media 804 may represent a fixed or removable component of the computing device 800. Further, any instance of the computer-readable storage media 804 may provide volatile or non-volatile retention of information.

The computing device 800 can utilize any instance of the computer-readable storage media 804 in different ways. For example, any instance of the computer-readable storage media 804 may represent a hardware memory unit (such as Random Access Memory (RAM)) for storing transient information during execution of a program by the computing device 800, and/or a hardware storage unit (such as a hard disk) for retaining/archiving information on a more permanent basis. In the latter case, the computing device 800 also includes one or more drive mechanisms 808 (such as a hard drive mechanism) for storing and retrieving information from an instance of the computer-readable storage media 804.

The computing device 800 may perform any of the functions described above when the hardware processor(s) 802 carry out computer-readable instructions stored in any instance of the computer-readable storage media 804. For instance, the computing device 800 may carry out computer-readable instructions to perform each block of the methods described in relation to FIGS. 1 to 6.

Alternatively, or in addition, the computing device 800 may rely on one or more other hardware logic components 810 to perform operations using a task-specific collection of logic gates. For instance, the hardware logic component(s) 810 may include a fixed configuration of hardware logic gates, e.g., that are created and set at the time of manufacture, and thereafter unalterable. Alternatively, or in addition, the other hardware logic component(s) 810 may include a collection of programmable hardware logic gates that can be set to perform different application-specific tasks. The latter category of devices includes, but is not limited to Programmable Array Logic Devices (PALs), Generic Array Logic Devices (GALs), Complex Programmable Logic Devices (CPLDs), Field-Programmable Gate Arrays (FPGAs), etc.

FIG. 8 generally indicates that hardware logic circuitry 812 includes any combination of the hardware processor(s) 802, the computer-readable storage media 804, and/or the other hardware logic component(s) 810. That is, the computing device 800 can employ any combination of the hardware processor(s) 802 that execute machine-readable instructions provided in the computer-readable storage media 804, and/or one or more other hardware logic component(s) 810 that perform operations using a fixed and/or programmable collection of hardware logic gates. More generally stated, the hardware logic circuitry 812 corresponds to one or more hardware logic components of any type(s) that perform operations based on logic stored in and/or otherwise embodied in the hardware logic component(s).

In some cases, the computing device 800 may also include an input/output interface 814 for receiving various inputs (via input devices 816), and for providing various outputs (via output devices 818). For instance, the computing device 800 may include such input/output device 814 if said device 800 represents a client device 908.1 to 908.n of FIG. 9. Illustrative input devices include a keyboard device, a mouse input device, a touchscreen input device, a digitizing pad, one or more static image cameras, one or more video cameras, one or more depth camera systems, one or more microphones, a voice recognition mechanism, any movement detection mechanisms (e.g., accelerometers, gyroscopes, etc.), and so on. One particular output mechanism may include a display device 820 and an associated graphical user interface presentation (GUI) 822. The display device 820 may correspond to a liquid crystal display device, a light-emitting diode display (LED) device, a cathode ray tube device, a projection mechanism, etc. Other output devices include a printer, one or more speakers, a haptic output mechanism, an archival mechanism (for storing output information), and so on. The computing device 800 may also include one or more network interfaces 824 for exchanging data with other devices via one or more communication conduits 826. One or more communication buses 828 may communicatively couple the above-described components together.

The communication conduit(s) 826 may be implemented in any manner, e.g., by a local area computer network, a wide area computer network (e.g., the Internet), point-to-point connections, etc., or any combination thereof. The communication conduit(s) 826 may include any combination of hardwired links, wireless links, routers, gateway functionality, name servers, etc., governed by any protocol or combination of protocols.

FIG. 8 shows the computing device 800 as being composed of a discrete collection of separate units. In some cases, the collection of units may correspond to discrete hardware units provided in a computing device chassis having any form factor.

Turning to FIG. 9, there is shown an Internet-based system 900 which may be used to implement the methods described in relation to FIGS. 1 to 6. The system 900 may comprise a server 902 which may be accessed via a network 906, such as the Internet, by one or more clients 908.1 to 908.n. The server may correspond to the apparatus described in relation to FIG. 8. The server may be an HTTP server and may be accessed via conventional Internet web-based technology. The server 902 may be connected to a database 904. The database 904 may store color prediction model(s), optical data of individual color components and/or condition adaption parameters. The database 904 may also store correction terms determined by the server. The clients 908.1 to 908.n may be computer terminals accessible by a user and may be customized devices, such as data entry kiosks, or general-purpose devices, such as a personal computer. The clients 908.1 to 908.n may comprise a screen and may be used to display the determined correction term and/or the determined color data and/or the determined second adjusted sample coating formulation. A printer 910 may be connected to a client terminal 908. The clients 908.1 to 908.n may be connected to a database 912. The database 912 may store reference coating data and/or first adjusted sample coating data and/or formulations associated with the adjusted sample coating or the second adjusted sample coating. The internet-based system 900 may be particular useful, if a service is provided to customers or in a larger company setup. A client 908 may be used to provide reference coating data and adjusted sample coating data to the computer processor of the server.

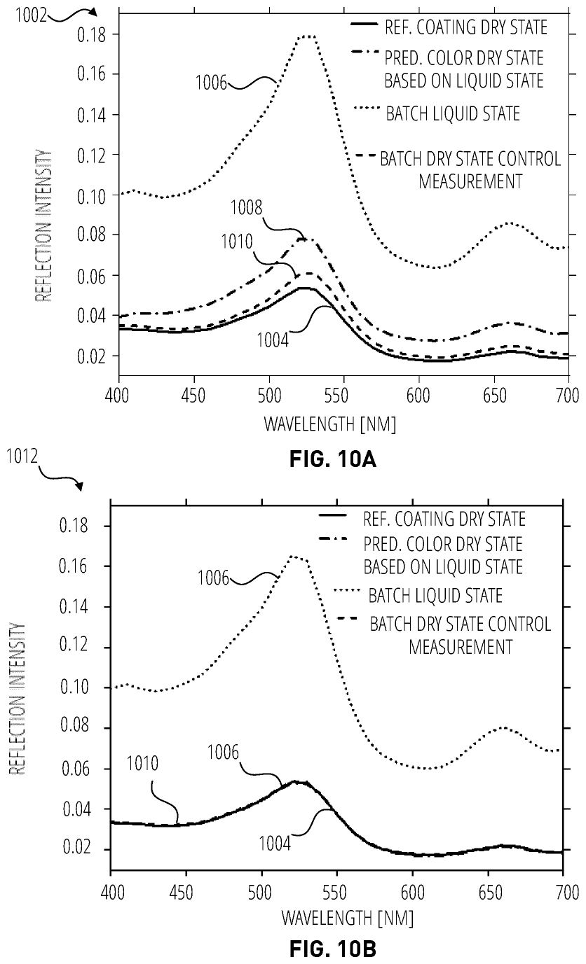

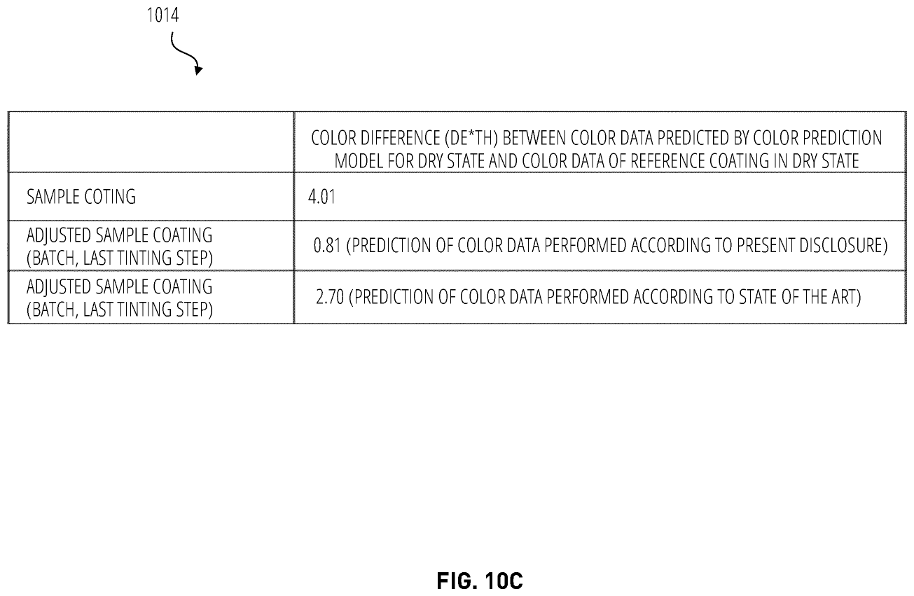

FIG. 10A illustrates a graph 1002 containing measured reflectance spectra 1004 of a green reference coating present in the dry state, measured reflectance spectra 1006 of an adjusted green sample coating material present in the wet state, reflectance spectra 1008 of the adjusted green sample coating material predicted for the dry state using the method described in WO 2022/122777 A1 as well as the measured reflectance spectra 1010 of the green adjusted sample coating prepared from the adjusted green sample coating material and being present in the dry state (used as control measurement to determine the quality of the color prediction accuracy). The adjusted green sample coating formulation may be determined using the method described in WO 2022/122777 A1 and may be used to prepare the adjusted green sample coating in the dry state, for example by applying said formulation to a substrate and drying and/or curing said applied formulation. The deviation in the reflectance spectra 1004, 1010 between the green reference coating and the adjusted green sample coating is also reflected in the color data shown in the Table 1014 of FIG. 10C. The deviation seems to be due to the fact that the systematical error of the color prediction model was determined with the method described in WO 2022/122777 A1 for the wet state of the adjusted green sample coating and this determined systematical error was assumed to be corresponding to the systematical error of the color prediction model for the dry state of said adjusted green sample coating. This assumption, however, does not seem to be accurate as is demonstrated by the color data shown in the Table 1014 of FIG. 10C. Depending on the scale of the difference between the systematical error of the color prediction model associated with the wet and the dry sate, the prediction of the color data can be significantly inaccurate as demonstrated in FIG. 10C.

FIG. 10B illustrates a graph 1012 containing color data of the green reference coating and green adjusted sample coating described in relation to FIG. 10A. The graph contains a measured reflectance spectra 1004 of the green reference coating present in the dry state, measured reflectance spectra 1006 of the adjusted green sample coating material present in the wet state, reflectance spectra 1008 of the adjusted green sample coating material predicted for the dry state using the methods described in relation to FIGS. 1 to 6 and measured reflectance spectra 1010 of the adjusted green sample coating in the dry state (used as control measurement to determine the quality of the color prediction accuracy). From graph 1012, no deviations between the measured reflectance spectra 1004 of the green reference coating, the measured reflectance spectra 1010 of the adjusted green sample coating and the predicted reflectance spectra 1008 of the adjusted green sample coating are detectable. The higher accuracy of the methods disclosed herein compared to the method described in WO 2022/122777 A1 seems to be due to the use of the correction term which allows to use input data associated with a wet state for the color prediction model to accurately predict the color data, e.g. reflectance spectra, in the dry state.

FIG. 10C illustrates a table 1014 containing a comparison of color differences for color data shown in FIGS. 10A and 10B, i.e. for color data of the green reference coating measured in the dry state (i.e. for a cured green reference coating prepared by applying reference coating material(s) to a substrate and drying and/or curing the applied reference coating material(s)) and color data predicted for the green sample coating (first row) or adjusted green sample coating for the dry state using the methods disclosed herein as well as the method (middle row) disclosed in WO 2022/122777 A1 (last row). As can be seen in the first row, the green sample coating has a rather large color difference from the green reference coating. This is due to the fact that the green sample coating material is prepared using reduced amounts of colorants to avoid overshooting colorant concentrations. The second row illustrates that use of the correction term determined according to the methods disclosed herein, for example determined according to FIGS. 1 to 3C, results in a significantly reduced color difference if said correction term is used for prediction of the color data using a color prediction model (for example as described in relation to FIGS. 4A and 4B) as compared to color prediction methods being devoid of the use of said term (e.g. the color prediction method described in WO 2022/122777 A1). The huge color difference between the predicted color data and the color data of the green reference coating may lead to incorrect predictions of further necessary adjustments such that the color difference is below a predefined threshold. In contrast, the significantly lower color difference obtained with the methods disclosed herein allow to more reliably predict the color of coatings present under second physical conditions, such as the dry state, using input data acquired under first physical conditions, such as the wet state. The improved accuracy allows to significantly reduce the amount of sprayouts (e.g. dried coatings) that need to be prepared to determine whether the adjustment calculated using the predicted color data is sufficiently accurate or not.

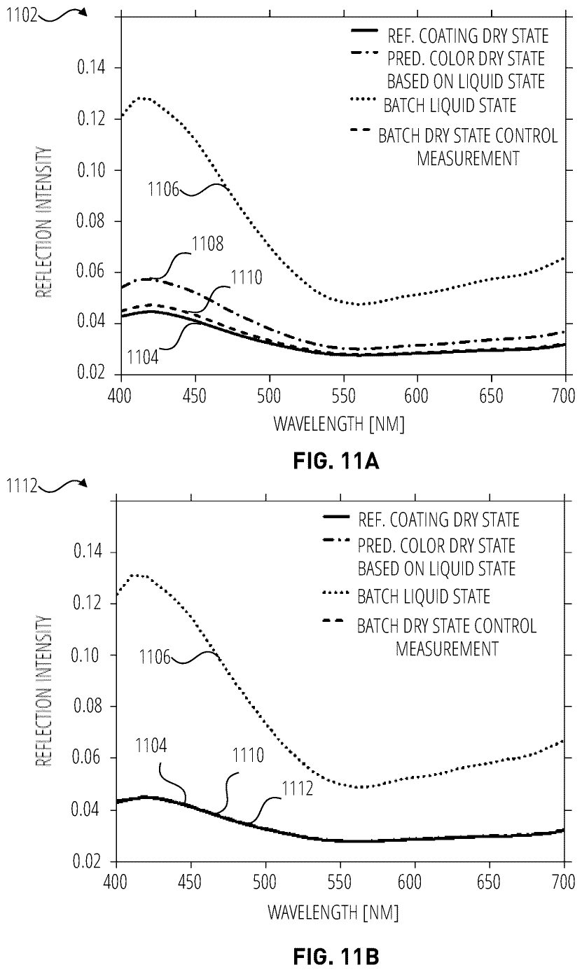

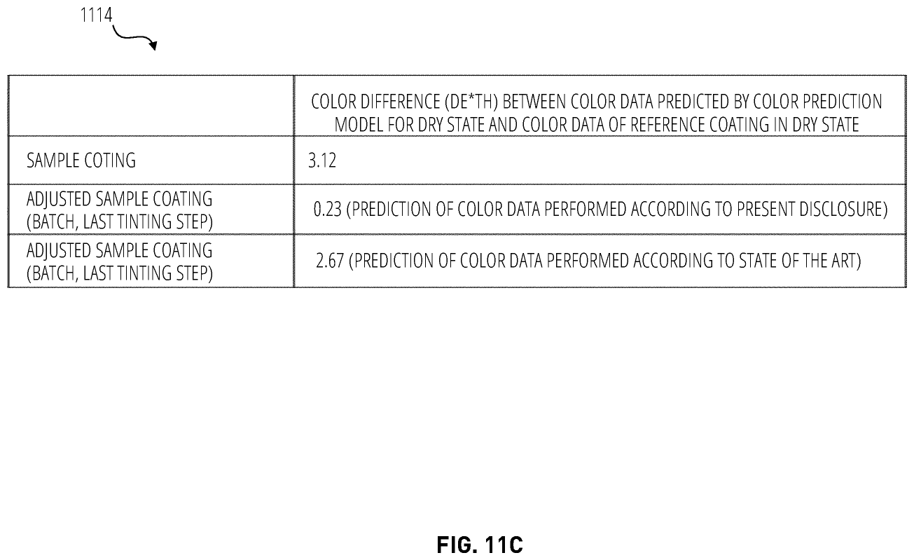

FIG. 11A illustrates another graph 1102 containing measured reflectance spectra 1104 of a blue reference coating present in the dry state, measured reflectance spectra 1106 of an adjusted blue sample coating material present in the wet state, reflectance spectra 1108 of the adjusted blue sample coating material predicted for the dry state using the method described in WO 2022/122777 A1 as well as the measured reflectance spectra 1110 of the adjusted blue sample coating present in the dry state and prepared from the adjusted blue sample coating material. The adjusted blue sample coating formulation may be determined using the method described in WO 2022/122777 A1 and may be used to prepare the adjusted blue sample coating as described in relation with FIG. 10A. The deviation in the reflectance spectra 1104, 1110 between the blue reference coating and the adjusted blue sample coating is also reflected in the color data shown in the Table 1114 of FIG. 11C.

FIG. 11B illustrates another graph 1112 containing color data of the blue reference coating and the adjusted blue sample coating described in relation to FIG. 11A. The graph contains a measured reflectance spectra 1104 of the blue reference coating present in the dry state, measured reflectance spectra 1106 of the adjusted blue sample coating material present in the wet state, reflectance spectra 1108 of the adjusted blue sample coating material predicted for the dry state using the methods described in relation to FIGS. 1 to 6 and measured reflectance spectra 1110 of the adjusted blue sample coating in the dry state. From graph 1112, no deviations between the measured reflectance spectra 1104 of the blue reference coating, the measured reflectance spectra 1110 of the adjusted blue sample coating and the predicted reflectance spectra 1108 of the adjusted blue sample coating are detectable.

FIG. 11C illustrates another table 1114 containing a comparison of color differences for color data shown in FIGS. 11A and 11B, i.e. for color data of the blue reference coating measured in the dry state (i.e. for a cured blue reference coating prepared by applying blue reference coating material(s) to a substrate and drying and/or curing the applied blue reference coating material(s)) and color data predicted for the blue sample coating (first row) or adjusted blue sample coating for the dry state using the methods disclosed herein (middle row) as well as the method disclosed in WO 2022/122777 A1 (last row). As can be seen in the first row, the blue sample coating has a rather large color difference compared to the blue reference coating. The second row illustrates that use of the correction term determined according to the methods disclosed herein, for example determined according to FIGS. 1 to 3C, results in a significantly reduced color difference if said correction term is used for prediction of the color data using a color prediction model (for example as described in relation to FIGS. 4A and 4B) as compared to color prediction methods being devoid of the use of said term (e.g. the color prediction method described in WO 2022/122777 A1).

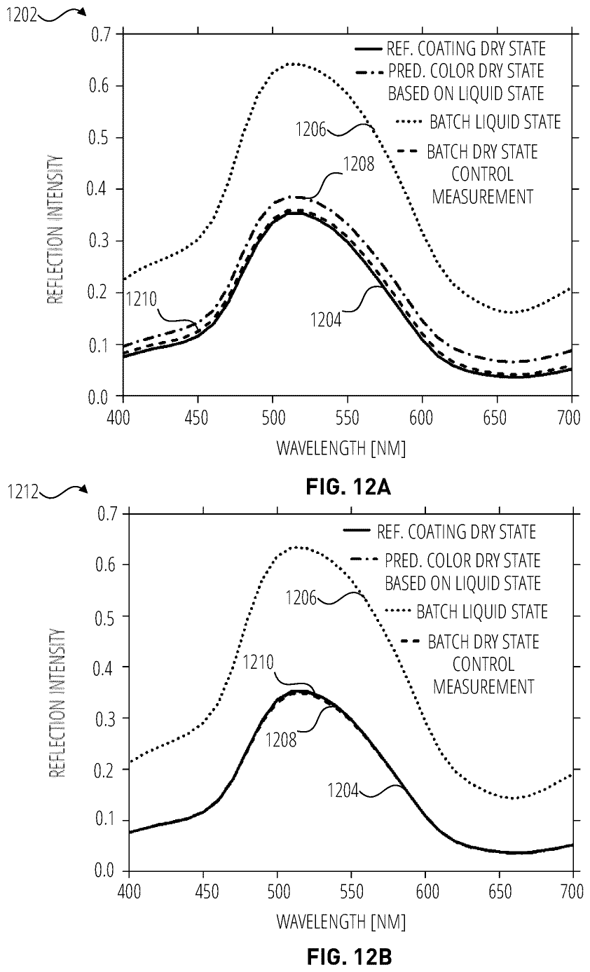

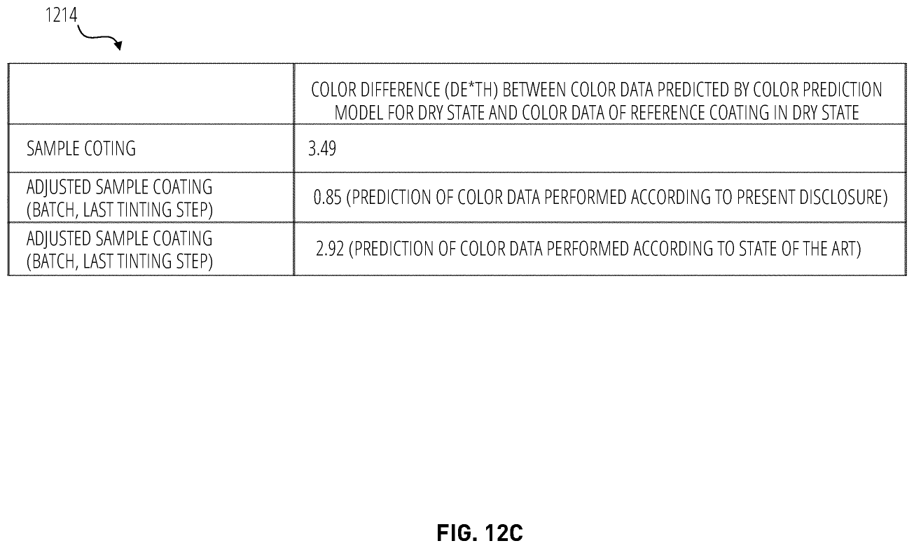

FIG. 12A illustrates yet another graph 1202 containing measured reflectance spectra 1204 of another green reference coating present in the dry state, measured reflectance spectra 1206 of another adjusted green sample coating material present in the wet state, reflectance spectra 1208 of the adjusted green sample coating material predicted using the method described in WO 2022/122777 A1 as well as the measured reflectance spectra 1210 of the adjusted green sample coating present in the dry state and prepared from the adjusted blue sample coating material. The adjusted blue sample coating formulation may be determined using the method described in WO 2022/122777 A1 and may be used to prepare the adjusted blue sample coating as describe in relation with FIG. 10A. The deviation in the reflectance spectra 1210, 1204 between the green reference coating and the adjusted green sample coating is also reflected in the color data shown in the Table 1214 of FIG. 12C.

FIG. 12B illustrates yet another graph 1212 containing color data of the green reference coating and the adjusted green sample coating described in relation to FIG. 12A. The graph contains a measured reflectance spectra 1204 of the green reference coating present in the dry state, measured reflectance spectra 1206 of the adjusted green sample coating material present in the wet state, reflectance spectra 1208 of the adjusted green sample coating material predicted for the dry state using the methods described in relation to FIGS. 1 to 6 and measured reflectance spectra 1210 of the adjusted green sample coating in the dry state. From graph 1212, no visual deviations between the measured reflectance spectra of the green reference coating 1204, the measured reflectance spectra 1210 of the adjusted green sample coating and the predicted reflectance spectra 1208 of the adjusted green sample coating are detectable.

FIG. 12C illustrates yet another table 1214 containing a comparison of color differences for color data shown in FIGS. 12A and 12B, i.e. for color data of the green reference coating measured in the dry state (i.e. for a cured green reference coating prepared by applying green reference coating material(s) to a substrate and drying and/or curing the applied green reference coating material(s)) and color data predicted for the green sample coating (first row) or adjusted green sample coating for the dry state using the methods disclosed herein (middle row) as well as the method disclosed in WO 2022/122777 A1 (last row). As can be seen in the first row, the green sample coating has a rather large color difference compared to the green reference coating. The second row illustrates that use of the correction term determined according to the methods disclosed herein, for example determined according to FIGS. 1 to 3C, results in a significantly reduced color difference if said correction term is used for prediction of the color data using a color prediction model (for example as described in relation to FIGS. 4A and 4B) as compared to color prediction methods being devoid of the use of said term (e.g. the color prediction method described in WO 2022/122777 A1).

In summary, the methods, apparatuses and computer elements disclosed herein allow to achieve more accurate predictions of color data of coatings present under a second physical condition, such as a dry state, when input data of the same coating being present under a first physical condition, such as a wet state, is used for the color prediction. The more accurate prediction of the color data using said correction term, which allows to transform the systematical error of the color prediction model from one physical condition to another physical condition, allows to more accurately determine adjusted sample coating formulations necessary to achieve a coating which fulfils the requirements of color matching in when compared to a reference coating, e.g. the color difference between the color data associated with the adjusted sample coating prepared from the determined adjusted sample coating formulation and the color data of a reference coating is below a defined threshold value.

The present disclosure has been described in conjunction with a preferred embodiment as examples as well. However, other variations can be understood and effected by those persons skilled in the art and practicing the claimed invention, from the studies of the drawings, this disclosure and the claims.

Any steps presented herein can be performed in any order. The methods disclosed herein are not limited to a specific order of these steps. It is also not required that the different steps are performed at a certain place, i.e. each of the steps may be performed at different computing nodes using different equipment/data processing.

In the claims as well as in the description the word “comprising” or “including” does not exclude other elements or steps and the indefinite article “a” or “an” does not exclude a plurality. A single element or other unit may fulfill the functions of several entities or items recited in the claims. The mere fact that certain measures are recited in the mutual different dependent claims does not indicate that a combination of these measures cannot be used in an advantageous implementation.

As used herein “determining” also includes “initiating or causing to determine”, “generating” also includes “initiating and/or causing to generate” and “providing” also includes “initiating or causing to determine, generate, select, send and/or receive”. “Initiating or causing to perform an action” includes any processing signal that triggers a computing node or device to perform the respective action.

Any disclosure and embodiments described herein relate to the methods, the apparatuses and the computer program elements lined out above and vice versa. Advantageously, the benefits provided by any of the embodiments and examples equally apply to all other embodiments and examples and vice versa.

1. A computer-implemented method for providing a correction term for a color prediction model, said correction term being associated with an adjusted sample coating being present under at least two different physical conditions, said method comprising:
receiving by at least one processor via a communication interface a request to provide
a color difference (CD1) between the measured color data of the adjusted sample coating being present under a first physical condition and the predicted color data of the adjusted sample coating being present under the first physical condition,
a color difference (CD2) between the measured color data of a sample coating being present under the second physical condition and the measured color data of the sample coating being present under the first physical condition, said sample coating being associated with the adjusted sample coating, and
a color difference (CD3) between the predicted color data of the adjusted sample coating being present under the second physical condition and the predicted color data of the adjusted sample coating being present under the first physical condition; and
in response to the received request, determining with the at least one processor the correction term for the color prediction model using the provided color differences (CD1) to (CD3); and
providing the determined correction term for the color prediction model via a communication interface.

2. The computer-implemented method of claim 1, wherein the first physical condition includes a wet state, or a physical condition associated with a first application process; and/or wherein the second physical condition includes a dry state, or a physical condition associated with a second application process.

3. The computer-implemented method of claim 1, wherein the color data includes reflectance data, color space data, such as CIEL*a*b* values or CIEL*C*h* values, gloss data, texture parameters, or a combination thereof.

4. The computer-implemented method of claim 1, wherein providing the predicted color data of the adjusted sample coating being present under the first physical condition includes
receiving model input data including adjusted sample coating formulation data and optical data of individual color components associated with the first physical condition,
receiving a color prediction model configured to predict color data of a coating using coating formulation data and optical data of individual color components, and
predicting said color data using the received color prediction model and the received model input data.

5. The computer-implemented method of claim 4, wherein providing the predicted color data of the adjusted sample coating being present under the first physical condition further includes considering the systematical error of the color prediction model associated with the first physical condition.

6. The computer-implemented method of claim 1, wherein providing the predicted color data of the adjusted sample coating being present under the second physical condition includes
receiving model input data including adjusted sample coating formulation data and optical data of individual color components associated with the second physical condition or including adjusted sample coating formulation data, optical data of individual color components associated with the first physical condition and condition adaption parameters associated with the difference between the first and the second physical condition of the sample coating,
receiving a color prediction model configured to predict color data of a coating using coating formulation data, optical data of individual color components and optionally condition adaption parameters, and
predicting said color data using the received color prediction model and the received model input data.

7. The computer-implemented method of claim 6, wherein the condition adaption parameters are pre-configured and/or are calculated using a method configured to optimize condition adaption parameters by minimizing a cost function starting from a given set of initial condition adaption parameters and a color prediction model configured to predict the color data of coatings being present under the first physical condition by using as input data the formulation of the coatings, specific optical data of individual color components present within the formulations of the coatings, and condition adaption parameters resulting from the method.

8. The computer-implemented method of claim 6, wherein providing the predicted color data of the adjusted sample coating being present under the second physical condition further includes considering the systematical error of the color prediction model associated with the second physical condition.

9. The computer-implemented method of claim 1, wherein the correction for the color prediction model using the provided color difference (CD1) to (CD3) is determined according to formula (I):
$$correction term = C D 1 \times \frac{Δ C D sample {coating}_{first phys . cond . \to second phys . cond .}^{measured}}{Δ C D adj . sample {coating}_{first phys . cond . \to second phys . cond .}^{predicted}}$$
(I), wherein the numerator of the fraction corresponds to color difference (CD2) and the denominator of said fraction corresponds to color difference (CD3).

10. A computer-implemented method for determining the color data of an adjusted sample coating being present under second physical conditions based on color data of the adjusted sample coating being present under first physical conditions, said method comprising:
receiving by at least one processor via a communication interface a request to provide
a color difference between the measured color data of a sample coating being present under the second physical condition and the predicted color data of the sample coating being present under the second physical condition, said sample coating being associated with the adjusted sample coating,
optical data of individual color components associated with the first physical condition,
adjusted sample coating data including the formulation of the adjusted sample coating,
condition adaption parameters associated with the difference between the first and the second physical condition of the adjusted sample coating,
a correction term for the color prediction model determined according to the method of claim 1,
a color prediction model configured to predict the color of the adjusted sample coating being present under the second physical condition by using as input data the color difference, the optical data of individual color components, the condition adaption parameters, the adjusted sample coating data, and the correction term; and
in response to the request, determining with the at least one processor the color data of the adjusted sample coating being present under the second physical condition using the color prediction model and the data provided in step (a); and
providing the determined color data of the adjusted sample coating being present under the second physical condition via the communication interface.

11. A computer-implemented method for determining a second adjusted sample coating formulation to match the color of a reference coating being present under a second physical conditions based on color data of a first adjusted sample coating being present under a first physical condition, said method comprising:
receiving by at least one processor via a communication interface a request to provide
a color difference between the measured color data of a sample coating being present under the second physical condition and the predicted color data of the sample coating being present under the second physical condition, said sample coating being associated with the first adjusted sample coating,
optical data of individual color components associated with the first physical condition,
reference coating data including color data of the reference coating being present under the second physical conditions,
first adjusted sample coating data including the formulation of the first adjusted sample coating,
condition adaption parameters associated with the difference between the first and the second physical condition of the first adjusted sample coating,
a correction term for the color prediction model determined according to the method of claim 1,
a color prediction model configured to predict the color of the second adjusted sample coating being present under the second physical condition by using as input data the color difference, the optical data of individual color components, the reference coating data, the first adjusted sample coating data, the condition adaption parameters, and the correction term; and
in response to the request, determining with the at least one processor a second adjusted sample coating formulation using the color prediction model and provided data; and
providing the determined second adjusted sample coating formulation via the communication interface.

12. An apparatus comprising:
one or more computing nodes; and one or more computer-readable media having thereon computer-executable instructions which, when executed by the one or more computing nodes, cause the apparatus to perform the methods as claimed in method of claim 1.

13. Use of A method of using a correction term as determined according to the method of claim 1, the method comprising using the correction term to improve the accuracy of color data of an adjusted sample coating being present under a second physical condition, the color data being predicted by a color prediction model based on color data of the adjusted sample coating being present under first physical conditions.

14. A computer program element comprising instructions, which when executed by one or more computing node(s) or a computing system, direct the computing node(s) or the computing system to carry out the steps of the method of claim 1.

15. A computer program element comprising instructions, which when executed by an apparatus of claim 13, direct the apparatus to carry out the steps of the method of claim 1.

16. An apparatus comprising:
one or more computing nodes; and one or more computer-readable media having thereon computer-executable instructions which, when executed by the one or more computing nodes, cause the apparatus to perform the method of claim 10.

17. A computer program element comprising instructions, which when executed by an apparatus, direct the apparatus to carry out the steps of the method of claim 10.

18. An apparatus comprising:
one or more computing nodes; and one or more computer-readable media having thereon computer-executable instructions which, when executed by the one or more computing nodes, cause the apparatus to perform the method of claim 11.

19. A computer program element comprising instructions, which when executed by an apparatus, direct the apparatus to carry out the steps of the method of claim 11.
